(19) United States
(12) Patent Application Publication
(10) Pub. No.: US 2001/0017417 A1
(43) Pub. Date: Aug. 30, 2001

(54) SEMICONDUCTOR DEVICE WITH A CONDDUCTIVE METAL LAYER ENGAGING NOT LESS THAN FIFTY PERCENT OF A SOURCE\DRAIN REGION

(76) Inventor: HIDEAKI KURODA, KANAGAWA (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/052,564

(22) Filed: Mar. 31, 1998

(30) Foreign Application Priority Data
Dec. 8, 1995 (JP) P07-345676
Sep. 20, 1996 (JP) P08-271797

(51) Int. Cl. H01L 23/48; H01L 23/52; H01L 29/40

(52) U.S. Cl. 257/758

(57) ABSTRACT

A semiconductor device includes a transistor element having a gate electrode, a source•drain region and a channel region, a first interlayer insulator formed on the transistor element, a second interlayer insulator formed on the first interlayer insulator, an interconnecting line formed on the second interlayer insulator, a conductive material filling layer formed by burying a conductive material in a first hole which is formed in the first interlayer insulator on the source•drain region, and a contact plug formed in a second hole which is formed in the second interlayer insulator. This semiconductor device has a low sheet resistance, can perform high-speed operation and increase the degree of integration, has high reliability, and does not largely increase the number of fabrication steps. A method of fabricating the semiconductor device is also provided.

### BACKGROUND OF THE INVENTION

1. Field of the Invention

The present invention relates to a semiconductor device having a diffusion region such as a source drain region and a method of fabricating the same.

2. Description of the Related Art

To miniaturize, for example, a field-effect semiconductor device, it is necessary to suppress the short-channel effect by making a source•drain region as a diffusion region shallow. However, if a diffusion region is made shallow, the sheet resistance in this diffusion region increases to make the speed of the operation of the semiconductor device difficult to increase. Therefore, a semiconductor device in which the surface of a diffusion region is silicified in self-alignment is being studied.

FIGS. 1A to 4 show one related art of a semiconductor device of this sort and its fabrication method. In this related art, as shown in FIG. 1A, an isolation region 211 made of an SiO₂ film is formed in a semiconductor substrate 210 as an Si substrate by a LOCOS method or the like. A gate oxide film 212 as an SiO₂ film is formed on the surface of an active region surrounded by the isolation region 211. Thereafter, a W silicide layer 214 is stacked on a polysilicon layer 213 containing an impurity to form a W polycide layer on the entire surface. An insulating film 216 which is an SiO₂ film and serves as an offset insulating film is deposited on the W polycide layer by a CVD method. The insulating film 216 and the W polycide layer are then patterned to form gate electrodes 215 made of the W polycide layer. As shown in FIG. 1B, the insulating film 216 and the isolation region 211 are used as masks to ion-implant an impurity into the semiconductor substrate 210 to form lightly doped diffusion regions 217 for an LDD structure.

Next, as shown in FIG. 2A, so-called gate side walls 218 made of an SiO₂ film are formed on the side surfaces of the gate electrodes 215 and the insulating film 216. As shown in FIG. 2B, a metal film 219 which is, e.g., a Ti film or a Co film is deposited on the entire surface, and an impurity is ion-implanted into the semiconductor substrate 210 through this metal film 219, thereby forming heavily doped diffusion regions 220 as source•drain regions.

As shown in FIG. 3A, an annealing is performed to activate the ion-implanted impurity and react the metal film 219 with the semiconductor substrate 210 to form a silicide layer 219A, which is, e.g., a Ti silicide layer or a Co silicide layer, on the surface of the heavily doped diffusion regions 220 in self-alignment. Thereafter, as shown in FIG. 3B, an unreacted metal film 219 on the insulating film 216, the gate side walls 218 and the isolation region 211 is removed.

Next, as shown in FIG. 4, an interlayer insulator 230 having a flat surface is formed, and holes 231 reaching the silicide layer 219A are formed in the interlayer insulator 230 by an RIE method. These holes 231 are filled with a TiN layer/Ti layer 232 and a contact plugs 233 made of W. Thereafter, interconnecting lines 234 made of an Al-based alloy are formed and well-known processes are executed to complete the semiconductor device of this related art.

In the above related art, however, the semiconductor substrate 210 and the metal film 219 are directly reacted with each other to form the silicide layer 219A, and this produces large stress in the semiconductor substrate 210. In addition, the reaction of the semiconductor substrate 210 with the metal film 219 hardly takes place uniformly. Therefore, the thickness of the silicide layer 219A becomes nonuniform to locally form a thick silicide layer 219A. A phenomenon called alloy spike in which this thick silicide layer 219A breaks through the diffusion regions 217 and 220 increases the probability of a junction leak occurring in the diffusion regions 217 and 220. This lowers the reliability of the semiconductor device.

If an annealing at a temperature of 850° C. or higher is performed to reflow the interlayer insulator 230 which is, e.g., a BPSG film, crystal grains grow in the silicide layer 219A and separate from each other to raise the sheet resistance in the diffusion regions 220. Accordingly, it is difficult to obtain an interlayer insulator 230 having a flat surface by simply reflowing the interlayer insulator 230 as a BPSG film. Therefore, it is indispensable to planarize the surface of the interlayer insulator 230 by some other method, and this increases the fabrication cost of the semiconductor device.

### OBJECT AND SUMMARY OF THE INVENTION

It is, therefore, an object of the present invention to provide a semiconductor device which has a low sheet resistance in a diffusion region and can perform high-speed operation, can increase the degree of integration, has high reliability, and does not largely increase the number of fabrication steps, and a method of fabricating the same.

A first semiconductor device according to the present invention is characterized by comprising a transistor element having a source•drain region, a channel region and a gate electrode formed on a semiconductor substrate, a first interlayer insulator formed on the transistor element, a second interlayer insulator formed on the first interlayer insulator, an interconnecting line formed on the second interlayer insulator, a conductive material filling layer having at least two layers formed by burying a conductive material in a first hole which is formed in the first interlayer insulator on the source•drain region and exposes 50% or more of an area of the source•drain region, and a contact plug formed in a second hole which is formed in the second interlayer insulator and connecting the conductive material filling layer and the interconnecting line.

In the first semiconductor device according to the present invention, it is desirable that the area of the bottom portion of the first hole be 50% or more, preferably 70% or more of the area of the source•drain region. Note that the upper limit of the area of the bottom portion of the first hole can be 100% or more of the area of the source•drain region. In contrast, the area of the bottom portion of the hole 231 in the aforementioned related art is about 10% of the area of the heavily doped diffusion region 220 as a source•drain region.

In the first semiconductor device according to the present invention, a conductive material filling layer can have a two-layered structure including an undercoating layer consisting of at least one of a metal and a metal compound and a conductive material layer. The conductive material filling layer can also have a three-layered structure including a polysilicon layer containing an impurity, an undercoating layer consisting of at least one of a metal and a metal compound, and a conductive material layer. Furthermore, the conductive material filling layer can have a three-layered structure including an undercoating layer consisting of at least one of a metal and a metal compound, a conductive material layer, and an insulating material layer. Examples of the material of the conductive material layer are refractory metals such as W and metals such as Cu and Al. Examples of the undercoating layer consisting of at least one of a metal and a metal compound are a two-layered structure including a Ti layer/a TiN layer stacked in this order from below, a Ti layer, a TiN layer, and a TiW layer. Examples of the impurity contained in the polysilicon layer are As and P in the case of an N-type semiconductor device and BF₂ and B in the case of a P-type semiconductor device.

A first semiconductor device fabrication method according to the present invention is characterized by comprising the steps of forming a gate electrode on a semiconductor substrate, forming a first interlayer insulator on the semiconductor substrate on which the gate electrode is formed, forming a transistor element having the gate electrode, a source•drain region and a channel region by forming a first hole in the first interlayer insulator and forming the source drain region in the semiconductor substrate exposed in a bottom portion of the first hole, forming a conductive material filling layer by burying a conductive material in the first hole, and forming a second interlayer insulator on the first interlayer insulator including the conductive material filling layer, forming a second hole in the second interlayer insulator on the conductive material filling layer, and forming a contact plug by filling the second hole with a conductive material.

A second semiconductor device fabrication method according to the present invention is characterized by comprising the steps of forming a gate electrode, a source•drain region and a channel region on a semiconductor substrate, forming a first interlayer insulator on the semiconductor substrate on which the gate electrode, the source•drain region and the channel region are formed, forming a first hole exposing not less than 50% of an area of the source•drain region in the first interlayer insulator and forming a conductive material filling layer having at least two layers by burying a conductive material in the first hole, and forming a second interlayer insulator on the first interlayer insolator including the conductive material filling layer, forming a second hole in the second interlayer insulator on the conductive material filling layer and forming a contact plug by filling the second hole with a conductive material.

In the second semiconductor device fabrication method according to the present invention, it is desirable that the area of the bottom portion of the first hole be 50% or more, preferably 70% or more of the area of the source•drain region. Note that the upper limit of the area of the bottom portion of the first hole can be 100% or more of the area of the source•drain region.

The first or second semiconductor device fabrication method according to the present invention has the first aspect in which the step of forming the conductive material filling layer comprises the steps of forming an undercoating layer consisting of at least one of a metal and a metal compound on the first interlayer insulator including the first hole, forming a conductive material layer on the undercoating layer, and removing the conductive material layer and the undercoating layer on the first interlayer insulator.

The first semiconductor device fabrication method according to the present invention has the second aspect in which the step of forming the conductive material filling layer comprises the steps of forming a polysilicon layer on the first interlayer insulator including the first hole, doping an impurity into the polysilicon layer and the underlaying undercoating layer consisting of at least one of a metal and a metal compound and a conductive material layer on the polysilicon layer, and removing the conductive material layer, the undercoating layer and the polysilicon layer on the first interlayer insulator. The second semiconductor device fabrication method according to the present invention also has the second aspect in which the step of forming the conductive material filling layer comprises the steps of forming a polysilicon layer containing an impurity on the first interlayer insulator including the first hole, sequentially forming an undercoating layer consisting of at least one of a metal and a metal compound and a conductive material layer on the polysilicon layer, and removing the conductive material layer, the undercoating layer and the polysilicon layer on the first interlayer insulator.

The first semiconductor device fabrication method according to the present invention has the third aspect in which the step of forming the conductive material filling layer comprises the steps of sequentially forming an undercoating layer consisting of at least one of a metal and a metal compound and a conductive material layer on the first interlayer insulator including the first hole, forming an insulating material layer on the conductive material layer, and removing the insulating material layer, the conductive material layer and the undercoating layer on the first interlayer insulator.

As the first and second interlayer insulators, it is possible to use a well-known insulating material such as SiO₂, BPSG, PSG, BSG, AsSG, SbSG, NSG, SOG, LTO (Low Temperature Oxide, low temperature CVD-SiO₂), SiN or SiON, or a stacked structure of these insulating materials.

In the present invention, when the contact resistance between the contact plug and the conductive material filling layer is low, the semiconductor device normally operates even if the conductive material filling layer is partially exposed to the bottom portion of the second hole.

A second semiconductor device having a memory cell region in which a memory cell electrically connected to a bit line is arranged, and a non-memory cell region in which a circuit except for the memory cell is arranged, according to the present invention is characterized by that a metal layer is stacked on a diffusion region formed in the semiconductor substrate in the non-memory cell region, the metal layer being the same layer as the bit line.

In the second semiconductor device according to the present invention, the memory cell can be constituted by using a capacitor. Also, the lowermost portion of the metal layer can be a barrier metal layer, or the metal layer itself can be a barrier metal layer.

A method of fabricating a third semiconductor device having a memory cell region in which a memory cell electrically connected to a bit line is arranged, and a non-memory cell region in which a circuit except for the memory cell is arranged, according to the present invention is characterized by comprising the steps of forming a hole for exposing a diffusion region of the non-memory cell in an interlayer insulator after forming a contact hole for the memory cell in the interlayer insulator, forming a metal layer electrically connected to the memory cell via the contact hole and filling the hole, and processing the metal layer into patterns corresponding to a pattern of the bit line and a pattern on the diffusion region.

In the first semiconductor device and the first and second semiconductor device fabrication methods according to the present invention, a conductive material filling layer for connecting a contact plug formed by a conventional technique and a source•drain region is formed below the contact plug. Therefore, the sheet resistance in the source•drain region including the conductive material filling layer can be lowered. Also, as the sheet resistance in the source drain region does not rise when metal crystal grains grow to separate from each other due to an annealing, the annealing is easy to perform. Additionally, since the semiconductor substrate and the conductive material filling layer do not directly react with each other, any stress that acts on the semiconductor substrate is small. Also, the probability of a junction leak occurring in the source•drain region due to alloy spike is low. Accordingly, the sheet resistance in the source•drain region can be greatly decreased without decreasing the fabrication yield of the semiconductor device. It is also possible to reliably avoid an increase in the junction leak.

Furthermore, it is only necessary to form a contact plug connected to the conductive material filling layer. Therefore, when the second hole is to be formed in the second interlayer insulator by using photolithography and dry etching, the process margin such as an allowable range of mask misalignment in the photolithography step can be increased. Consequently, the semiconductor device normally operates even if, e.g., about a ½ portion of the bottom of the contact plug is connected to the conductive material filling layer.

When the area of the bottom portion of the first hole is 50% or more of the area of the source•drain region, the sheet resistance in the source•drain region can be further lowered. Additionally, since the sheet resistance in the source•drain region can be lowered, the area of the source•drain region can be reduced. As a consequence, the semiconductor device can be operated at a high speed.

When the conductive material filling layer has a three-layered structure including a polysilicon layer containing an impurity, an undercoating layer consisting of at least one of a metal and a metal compound, and a conductive material layer, a source•drain region shallower by the thickness of the polysilicon layer can be formed in the semiconductor substrate. Additionally, since the conductive material layer is formed on the polysilicon layer, the sheet resistance can be lowered although the source•drain region is shallow.

When the conductive material filling layer has a three-layered structure including an undercoating layer consisting of at least one of a metal and a metal compound, a conductive material layer, and an insulating material layer, it is no longer necessary to completely fill the first hole with the conductive material layer whose step coverage is not so good. Consequently, the conductive material layer does not apply any large stress to the semiconductor substrate.

In the second semiconductor device according to the present invention, a metal layer which is the same layer as the bit line is stacked on the diffusion region in the non-memory cell region. Therefore, although it is unnecessary to add steps of forming and processing the metal layer, the sheet resistance in the diffusion region in the non-memory cell region is low. Accordingly, it is possible to mount both of a memory cell in the memory cell region and a high-speed circuit in the non-memory cell region without increasing the fabrication cost.

Also, when the lowermost portion of the metal layer is a barrier metal layer, the combination reaction of the semiconductor substrate with the metal layer in the non-memory cell region is suppressed by the barrier metal layer even though the metal layer is stacked on the diffusion region in the non-memory cell region. Consequently, a junction leak or the like caused by alloy spike can be reduced in the diffusion region in the non-memory cell region. Accordingly, the circuit in the non-memory cell region can operate rapidly and also has good characteristics.

When the metal layer is a barrier metal layer, the combination reaction of the semiconductor substrate with the metal layer in the non-memory cell region is suppressed although the metal layer is stacked on the diffusion region in the non-memory cell region. Consequently, a junction leak or the like caused by alloy spike can be reduced in the diffusion region in the non-memory cell region. Accordingly, the circuit in the non-memory cell region can operate rapidly and also has good characteristics. Additionally, since the structure of the metal layer is simpler than a stacked metal layer structure, the metal layer is easy to form. This results in a reduced fabrication cost.

In the third semiconductor device fabrication method according to the present invention, the hole for exposing the diffusion region in the non-memory cell region is filled with a metal layer which is the same layer as the bit line. Therefore, the sheet resistance in the diffusion region in the non-memory cell region can be lowered without adding steps of forming and processing the metal layer. Additionally, the hole for exposing the diffusion region in the non-memory cell region is formed after a contact hole of a bit line for a memory cell is formed. Accordingly, a junction leak in the memory cell can be prevented by filling the contact hole of the bit line for the memory cell with a plug made of a material different from the metal layer with which the hole is filled. Consequently, a semiconductor device mounting both a memory cell having good storage retention characteristics in the memory cell region and a high-speed circuit in the non-memory cell region can be fabricated at a low cost.

### BRIEF DESCRIPTION OF THE DRAWINGS

FIGS. 1A and 1B are schematic partial sectional views of a semiconductor substrate and the like for explaining a conventional fabrication method of a MOS transistor;

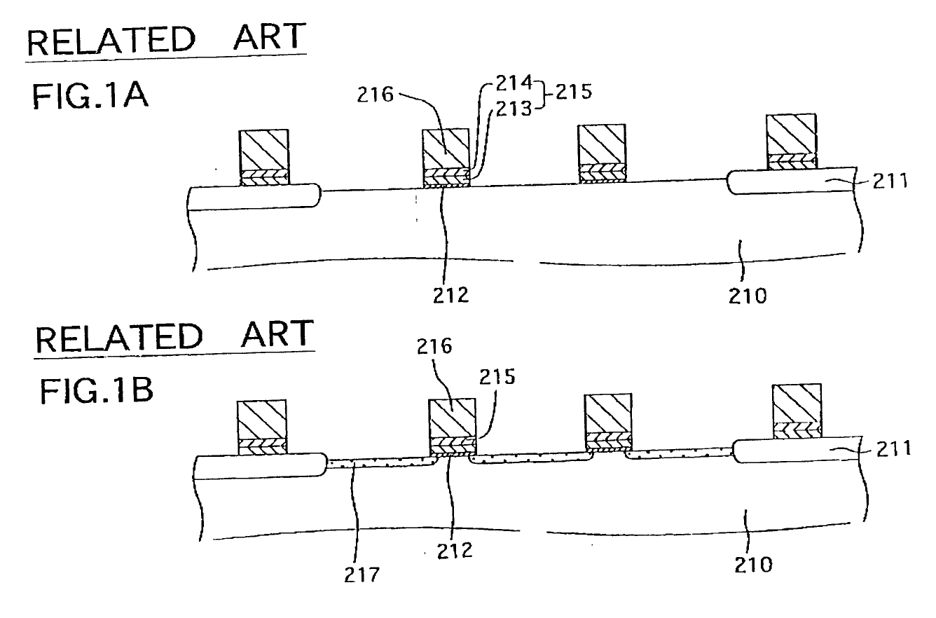

FIGS. 2A and 2B are schematic partial sectional views of the semiconductor substrate and the like for explaining the conventional fabrication method following FIGS. 1A and 1B;

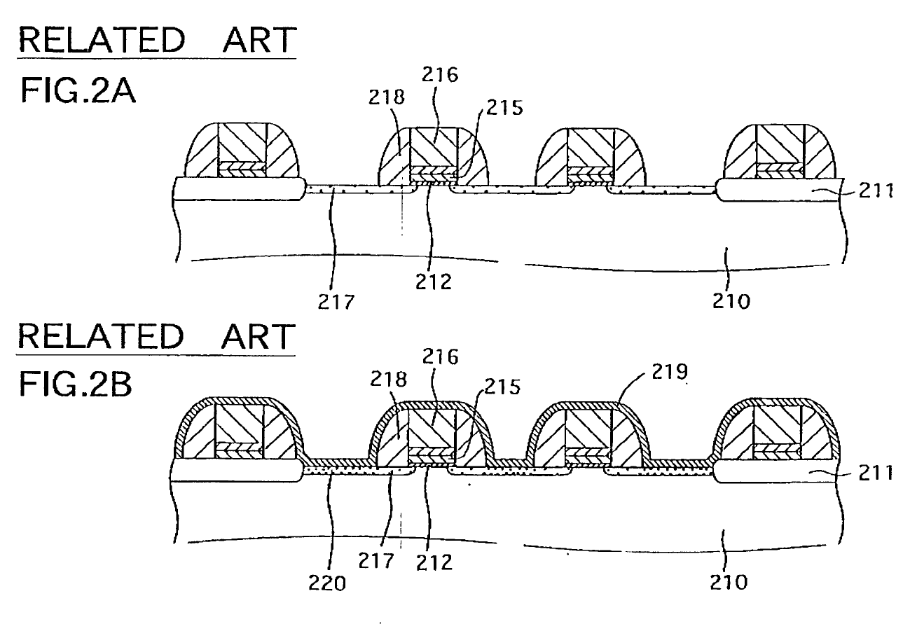

FIGS. 3A and 3B are schematic partial sectional views of the semiconductor substrate and the like for explaining the conventional fabrication method following FIGS. 2A and 2B;

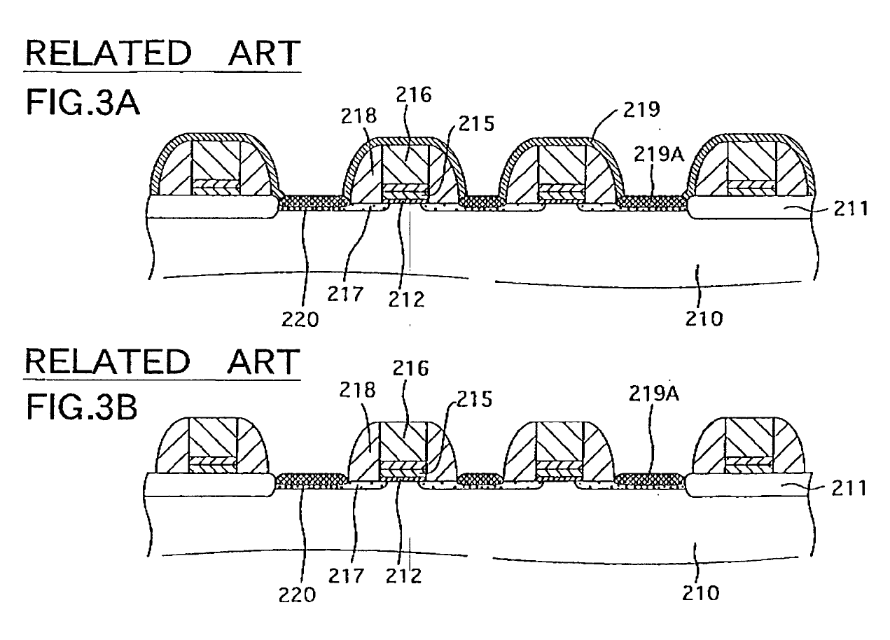

FIG. 4 is a schematic partial sectional view of the semiconductor substrate and the like for explaining the conventional fabrication method following FIGS. 3A and 3B;

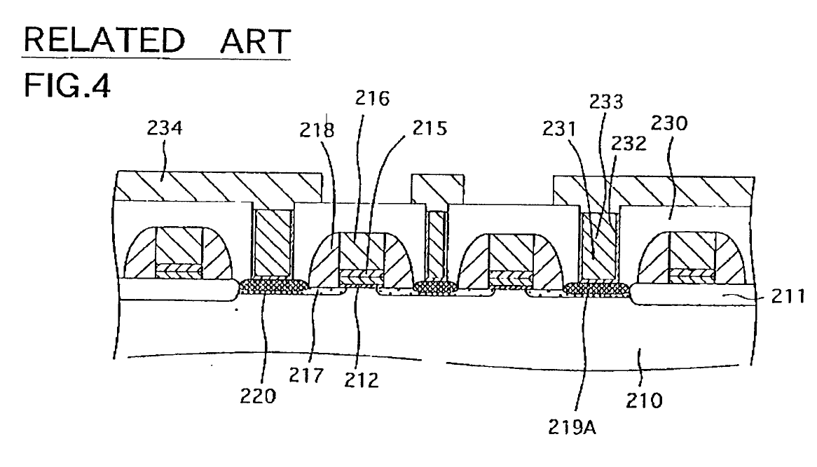

FIG. 5 is a schematic partial sectional view of a semiconductor device for explaining a semiconductor device and its fabrication method according to the first embodiment;

FIGS. 6A and 6B are schematic partial sectional views of the semiconductor substrate and the like for explaining the fabrication method of the semiconductor device of the first embodiment;

FIG. 7 is a schematic partial sectional view of the semiconductor substrate and the like for explaining the fabrication method of the semiconductor device of the first embodiment following FIGS. 6A and 6B;

FIG. 8 is a schematic partial sectional view of the semiconductor substrate and the like for explaining the fabrication method of the semiconductor device of the first embodiment following FIG. 7;

FIG. 9 is a schematic partial sectional view of the semiconductor substrate and the like for explaining the fabrication method of the semiconductor device of the first embodiment following FIG. 8;

FIG. 10 is a schematic partial sectional view of the semiconductor substrate and the like for explaining the fabrication method of the semiconductor device of the first embodiment following FIG. 9;

FIG. 11 is a schematic partial sectional view of the semiconductor substrate and the like for explaining the fabrication method of the semiconductor device of the first embodiment following FIG. 10;

FIG. 12 is a schematic partial plan view of a semiconductor device for explaining the arrangement of individual components of the semiconductor device of the first embodiment;

FIG. 13 is a schematic partial plan view of gate electrodes and the like for explaining the fabrication method of the semiconductor device of the first embodiment;

FIG. 14 is a schematic partial sectional view of a semiconductor substrate and the like for explaining the fabrication method of a semiconductor device of the second embodiment;

FIG. 15 is a schematic partial sectional view of the semiconductor substrate and the like for explaining the fabrication method of the semiconductor device of the second embodiment following FIG. 14;

FIG. 16 is a schematic partial sectional view of the semiconductor substrate and the like for explaining the fabrication method of the semiconductor device of the second embodiment following FIG. 15;

FIG. 17 is a schematic partial sectional view of a semiconductor device for explaining the fabrication method of a semiconductor device of the third embodiment;

FIG. 18 is a schematic partial sectional view of the semiconductor device for explaining the fabrication method of the semiconductor device of the third embodiment following FIG. 17;

FIGS. 19A and 19B are schematic partial sectional views of a semiconductor device for explaining the fabrication method of a semiconductor device of the fourth embodiment;

FIG. 20 is a schematic partial sectional view of the semiconductor device for explaining the fabrication method of the semiconductor device of the fourth embodiment following FIGS. 19A and 19B;

FIG. 21 is a schematic partial sectional view of the semiconductor device for explaining the fabrication method of the semiconductor device of the fourth embodiment following FIG. 20;

FIG. 22 is a schematic partial plan view of a semiconductor device for explaining the arrangement of individual components of the semiconductor device of the fourth embodiment;

FIG. 23 is a schematic partial plan view of gate electrodes and the like for explaining the fabrication method of the semiconductor device of the fourth embodiment;

FIG. 24 is a schematic partial sectional view of a semiconductor substrate and the like for explaining the fabrication method of a semiconductor device of the fifth embodiment;

FIG. 25 is a schematic partial sectional view of the semiconductor substrate and the like for explaining the fabrication method of the semiconductor device of the fifth embodiment following FIG. 24;

FIG. 26 is a schematic partial sectional view of a semiconductor substrate and the like for explaining the fabrication method of a semiconductor device of the sixth embodiment;

FIG. 27 is a schematic partial sectional view of the semiconductor substrate and the like for explaining the fabrication method of the semiconductor device of the sixth embodiment following FIG. 26;

FIG. 28 is a side sectional view showing the boundary between a memory cell region and a logic circuit region and the vicinity of the boundary in a semiconductor device according to the seventh embodiment of the present invention;

FIG. 29 is a plan view of the memory cell region of the semiconductor device of the seventh embodiment;

FIG. 30 is a plan view of the logic circuit region of the semiconductor device of the seventh embodiment;

FIGS. 31A to 31C are side sectional views showing steps in the first stage of the fabrication method of the semiconductor device according to the seventh embodiment in order;

FIGS. 32A and 32B are side sectional views showing steps in the second stage of the fabrication method of the semiconductor device according to the seventh embodiment in order;

FIG. 33 is a side sectional view showing a step in the third stage of the fabrication method of the semiconductor device according to the seventh embodiment;

FIG. 34 is a side sectional view showing the boundary between a memory cell region and a logic circuit region and the vicinity of the boundary in a semiconductor device according to the eighth embodiment of the present invention;

FIGS. 35A to 35C are side sectional views showing steps in the first stage of the fabrication method of the semiconductor device according to the eighth embodiment in order;

FIGS. 36A and 36B are side sectional views showing steps in the second stage of the fabrication method of the semiconductor device according to the eighth embodiment in order;

FIGS. 37A and 37B are side sectional views showing steps in the third stage of the fabrication method of the semiconductor device according to the eighth embodiment in order;

FIGS. 38A and 38B are side sectional views showing steps in the fourth stage of the fabrication method of the semiconductor device according to the eighth embodiment in order; and

FIG. 39 is a side sectional view showing the boundary between a memory cell region and a logic circuit region and the vicinity of the boundary in a semiconductor device according to the ninth embodiment of the present invention.

### DETAILED DESCRIPTION OF THE PREFERRED EMBODIMENTS

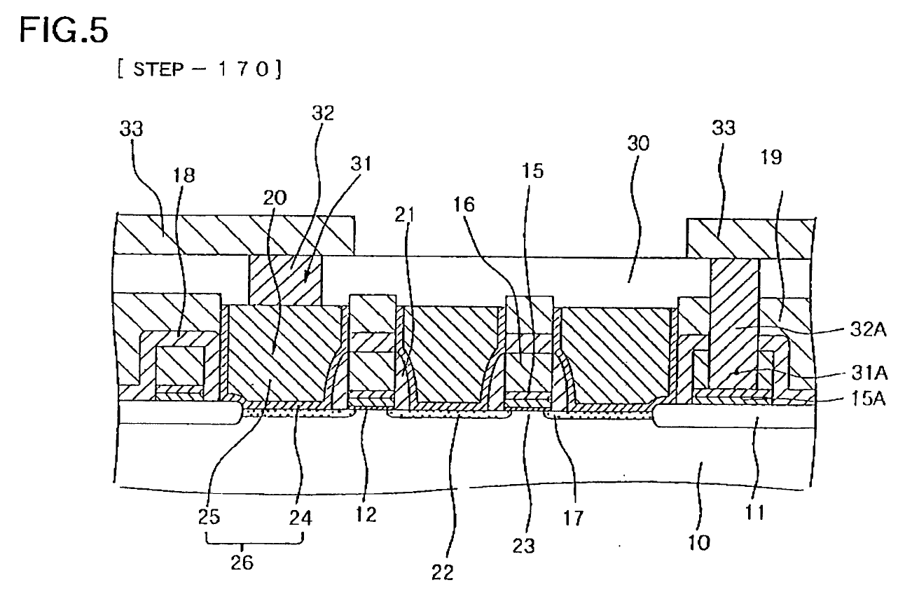

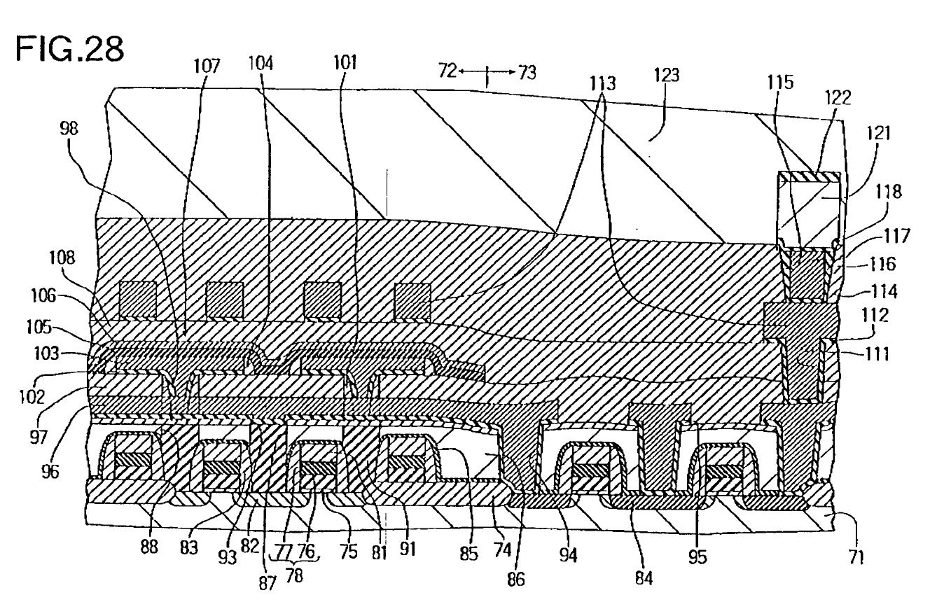

The first to sixth embodiments of the present invention in each of which the present invention is applied to a semiconductor device including a CMOS transistor and a method of fabricating the same will be described below with reference to FIGS. 5 to 27. Also, the seventh to ninth embodiments of the present invention in each of which the present invention is applied to a semiconductor device including a stacked capacitor type universal DRAM and a logic circuit which is a two-input NAND gate and a method of fabricating the same will be described below with reference to FIGS. 28 to 39.

(First Embodiment)

FIGS. 5 to 13 show the first embodiment. A fabrication method in this first embodiment is the first aspect of a first semiconductor device fabrication method according to the present invention. That is, the step of forming a conductive material filling layer in first holes has the steps of forming an undercoating layer consisting of at least one of a metal and a metal compound on a first interlayer insulator including the first holes, forming a conductive material layer on this undercoating layer, and removing the conductive material layer and the undercoating layer on the first interlayer insulator.

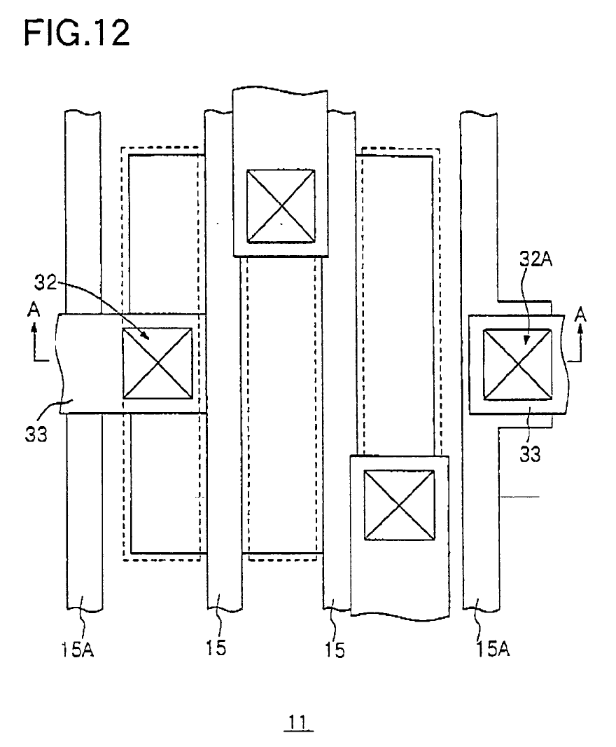

FIGS. 5 and 12 are a side sectional view and a plan view, respectively, of the semiconductor device of the first embodiment. The semiconductor device of this first embodiment comprises a transistor element, first interlayer insulators 18 and 19 formed on the transistor element, a second interlayer insulator 30 formed on the first interlayer insulators 18 and 19, and interconnecting lines 33 formed on the second interlayer insulator 30 and made of an Al-based alloy. The transistor element has source•drain regions 22. channel regions 23 and gate electrodes 15 formed on a semiconductor substrate 10.

The semiconductor device of the first embodiment further comprises a conductive material filling layer 26 formed by burying a conductive material in first holes 20 formed in the first interlayer insulators 18 and 19 on the source•drain regions 22, and contact plugs 32 which are formed in second holes 31 formed in the second interlayer insulator 30 and connect the conductive material filling layer 26 to the interconnecting lines 33. The first interlayer insulators 18 and 19 are constituted by a first insulating layer 18 which is an SiN film and a second insulating layer 19 which is a BPSG film.

The contact plugs 32 are made of W, and the second interlayer insulator 30 is an SiO₂ film. Even in the source•drain region 22 where the contact plug 32 need not be formed, the conductive material filling layer 26 is formed in the first hole 20 which is formed in the first interlayer insulators 18 and 19 above the source•drain region 22. The conductive material filling layer 26 has a two-layered structure including an undercoating layer 24 which also has a two-layered structure including a metal (more specifically, Ti) and a metal compound (more specifically, TiN), and a conductive material layer 25 (more specifically, a W layer).

A conductor pattern 15A (so-called word line) formed on an isolation region 11 and extending from the gate electrode of another transistor element is electrically connected to the interconnecting line 33 via a contact plug 32A formed in a hole 31A, which is formed in the first interlayer insulators 18 and 19 and the second interlayer insulator 30, and made of W.

The method of fabricating the semiconductor device of the first embodiment will be described below with reference to FIGS. 5 to 13. Although the semiconductor device of this first embodiment includes a CMOS transistor. FIGS. 5 to 13 show one of N- and P-type MOS transistors and its fabrication steps. Also, FIGS. 5 to 11 are side sectional views taken along a line A-A in FIG. 12.

[Step-100]

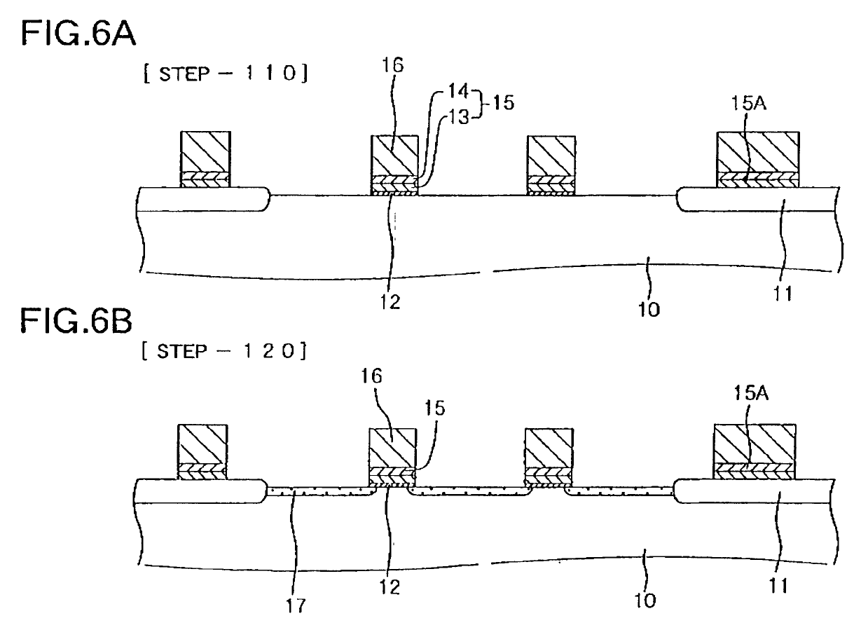

First, as shown in FIG. 6A, an isolation region 11 made of an SiO₂ film and an active region surrounded by this isolation region 11 are formed by well-known a LOCOS method on a semiconductor substrate 10 which is an Si substrate. Alternatively, an isolation region having a trench structure or the like can be formed instead of the isolation region 11 formed by a LOCOS method.

[step-110]

Next, the surface of the semiconductor substrate 10 is oxidized by a well-known method to form a gate oxide film 12 as an SiO₂ film. Thereafter, a W silicide layer 14 several tens to a hundred and several tens of nm thick is stacked on a polysilicon layer 13 several tens to a hundred and several tens of nm thick containing an impurity, thereby forming a W polycide layer on the entire surface. Next, an insulating film 16 which is an SiO₂ film several hundreds nm thick and serves as an offset insulating film is deposited on the W polycide layer by a CVD method. Thereafter, the insulating film 16, the W suicide layer 14 and the polysilicon layer 13 are patterned to simultaneously form gate electrodes 15 consisting of the W silicide layer 14 and the polysilicon layer 13 and conductor patterns 15A.

[Step-120]

Thereafter, as shown in FIG. 6B, an N-type Moo transistor formation region and a P-type MOS transistor formation region are alternately covered with resists (not shown), and these resists, the insulating film 16 and the isolation region 11 are used as masks to ion-implant an impurity into the semiconductor substrate 10 to form lightly doped diffusion regions 17. For example, As⁺ is used as an impurity for forming the lightly doped diffusion region 17 of an N-type MOS transistor, and BF₂⁺ or B⁺ is used as an impurity for forming the lightly doped diffusion region 17 of a P-type MOS transistor. In either case, the ion implantation is performed in a dose of 10¹² to 10¹⁴ cm⁻² at an acceleration energy of several tens of keV. Thereafter, an annealig is performed to activate the ion-implanted impurity.

[Step-130]

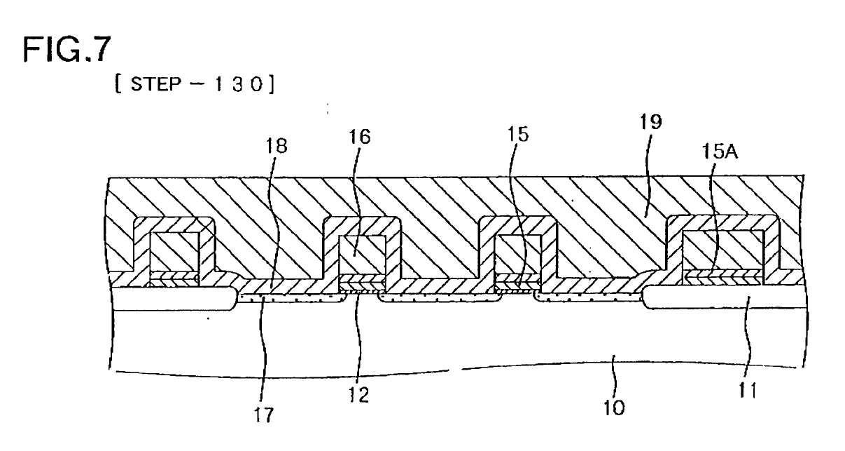

Next, as shown in FIG. 7, a first insulating film 18 which is an SiN film several tens to a hundred and several tens of nm thick is deposited on the entire surface by a low pressure CVD method. Consequently, the surfaces of the semiconductor substrate 10 and the isolation region 11, the side surfaces of the gate electrodes 15 and the conductor patterns 15A including the insulating film 16, and the top surface of the insulating film 16 are covered with the insulating layer 18. Note that an SiO₂ film several tens of nm thick can also be deposited before the insulating layer 18 as an SiN film is deposited. As a consequence, compared to the structure in which the insulating layer 18 is directly deposited, it is possible to alleviate the generation of stress in the semiconductor substrate 10 and prevent deterioration of the hot carrier resistance.

Thereafter, a second insulating layer 19 which is a BPSG film several hundred nm thick is deposited on the insulating layer 18 by a CVD method. Reflow is then performed at 800 to 900° C. to planarize the surface of the insulating layer 19. In this manner the first interlayer insulators 18 and 19 are formed on the entire surface.

[Step-140]

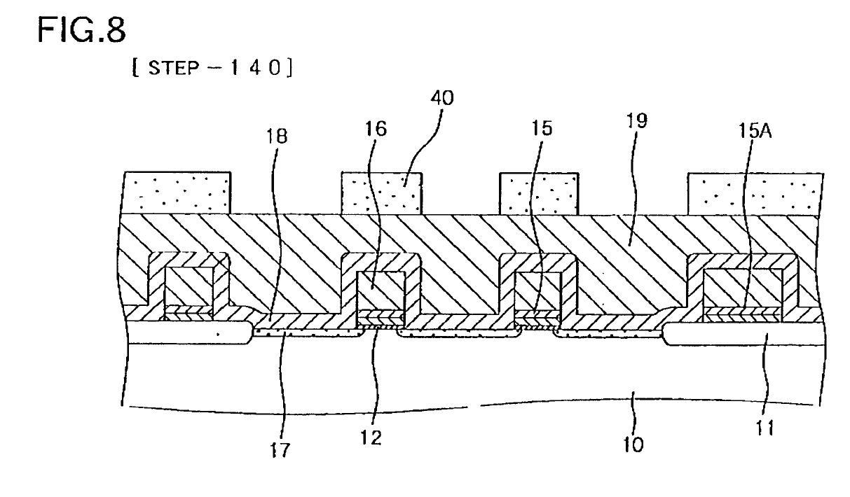

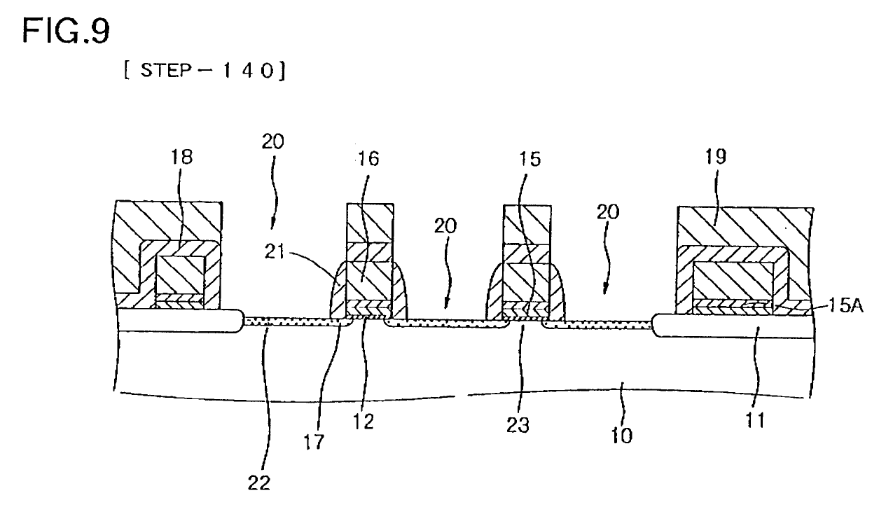

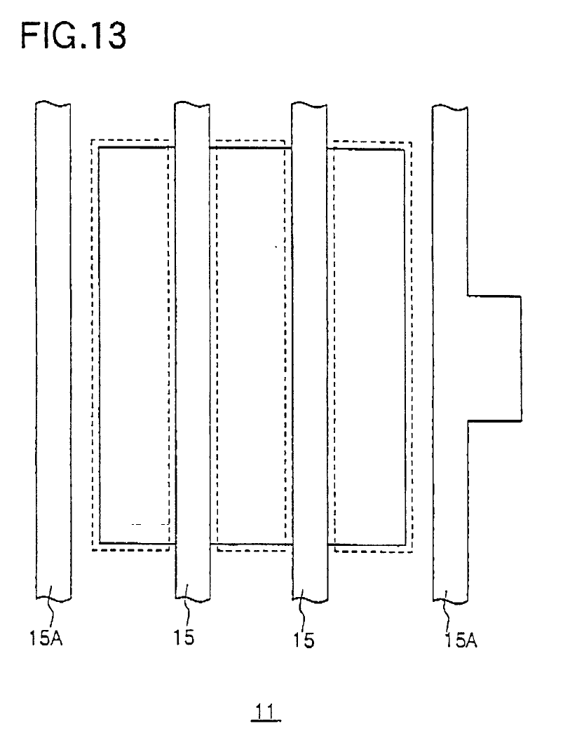

Next, as shown in FIG. 8, the insulating layer 19 is coated with a resist 40. This resist 40 is so patterned that regions where source•drain regions are to be formed are substantially entirely exposed between the gate electrodes 15 and the conductor patterns 15A as shown in FIG. 13. Referring to FIG. 13, the patterns of first holes corresponding to the hole patterns of the resist 40 are indicated by the dotted lines. Thereafter, as shown in FIG. 9, C₄F₈/CO-based etching gas is used to anisotropically etch the insulating layers 19 and 18 in this order to form first holes 20 in the first interlayer insulators 18 and 19. Gate side walls 21 made of the first insulating layer as an SiN film are formed on the side surfaces of the gate electrodes 15 including the insulating film 16.

Subsequently, the N-type MOS transistor formation region and the P-type MOS transistor formation region are alternately covered with resists (not shown), and these resists, the first interlayer insulators 18 and 19, the gate side walls 21 and the isolation region 11 are used as masks to ion-implant an impurity into the semiconductor substrate 10 to form source•drain regions 22 as heavily doped diffusion regions. For example, As⁺or P⁺ is used as an impurity for forming the source•drain region 22 of an N-type MOS transistor, and BF₂⁺ or B⁺is used as an impurity for forming the source•drain region 22 of a P-type MOS transistor. In either case, the ion implantation is performed in a dose of 10¹⁵ to 10¹⁶ cm² at an acceleration energy of several tens of keV. Thereafter, furnace annealing or rapid thermal annealing is performed at 800 to 1100° C. to activate the ion-implanted impurity. In this manner the source•drain regions 22 and channel regions 23 are formed to form a transistor element.

[Step-150]

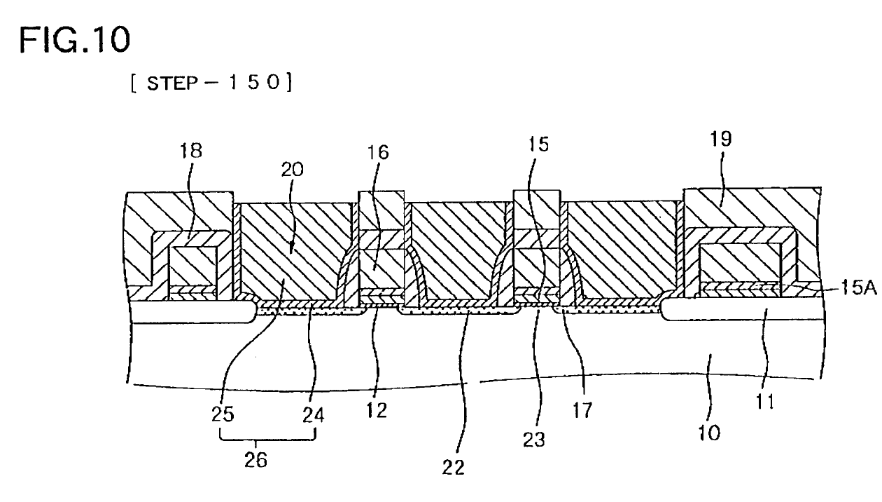

Thereafter, as shown in FIG. 10, a Ti layer and a TiN layer each having a thickness of several nm to several tens of nm are formed in this order by a sputtering method on the second insulating layer 19 including the first holes 20, thereby forming an undercoating layer 24. These Ti and TiN layers are formed to obtain an ohmic low contact resistance and to prevent damages to the semiconductor substrate 10 and improve the adhesion of W when W is deposited by a CVD method. Note that only one of the Ti and TiN layers can also be formed in some cases. Examples of the sputtering conditions of the Ti and TiN layers are as follows.

Ti layer (thickness: 30 nm)

| | |
|---|---|
| Process gas | Ar = 100 sccm |
| Pressure | 0.4 Pa |
| DC power | 5 kW |
| Substrate heating temperature | 150° C. |

TiN layer (thickness: 70 nm)

| | |
|---|---|
| Process gas | N₂/Ar = 80/30 sccm |
| Pressure | 0.4 Pa |
| DC power | 5 kW |
| Substrate heating temperature | 150° C. |

After the TiN layer is formed, it is desirable to perform annealing under, e.g., the following conditions in order to improve the barrier properties of this TiN layer.

| | |
|---|---|
| Ambient | nitrogen gas 100% |
| Temperature | 450° C. |
| Time | 30 min |

Thereafter, a conductive material layer 25 made of W is formed on the TiN layer by a so-called blanket W-CVD method. The thickness of this W layer is so chosen that the holes 20 are completely filled with the W layer. Examples of the formation conditions of the conductive material layer 25 are as follows.

| | |
|---|---|
| Gases used | WF₆/H₂/Ar = 75/500/2800 sccm |
| Pressure | 1.06 × 10⁴ Pa |
| Film formation temperature | 450° C. |

Next, the conductive material layer 25 and the undercoating layer 24 are sequentially etched back to form a conductive material filling layer 26 in the holes 20. Examples of the etching back conditions are as follows. Note that the conductive material layer 25 and the undercoating layer 24 can also be polished by a chemical mechanical polishing method (CMP method) instead of the etching back.

| | |
|---|---|
| Gases used | SF₆/Cl₂ = 25/20 sccm |
| Pressure | 1 Pa |
| Microwave power | 950 W |
| RF power | 50 W (2 MHz) |

[Step-160]

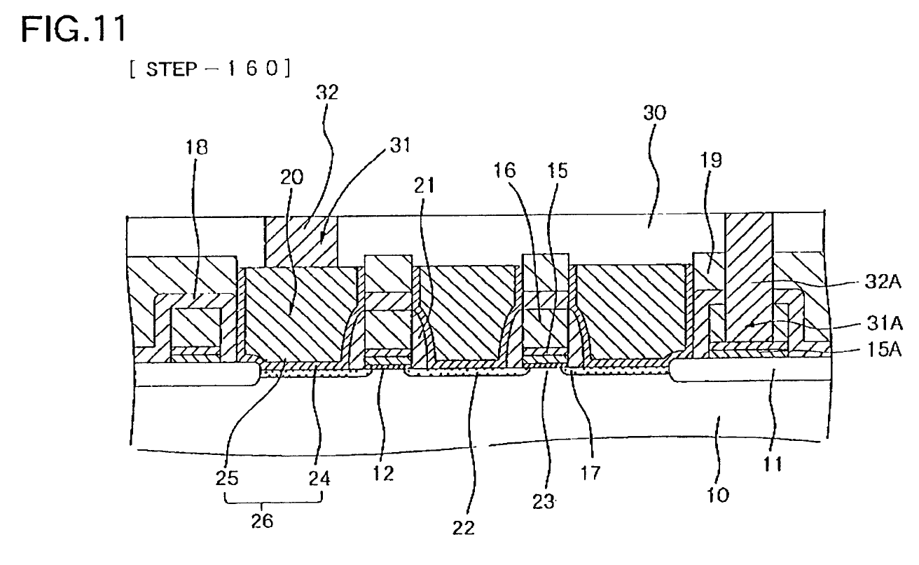

Thereafter, as shown in FIG. 11, a second interlayer insulator 30 which is, e.g., an SiO₂ film is deposited by a CVD method on the entire surface of the first interlayer insulators 18 and 19 including the conductive material filling layer 26. A second hole 31 reaching the conductive material filling layer 26 is then formed in the interlayer insulator 30 by an RIE method. The bottom portion of this hole 31 need not be entirely present on the conductive material filling layer 26. A contact plug 32 made of W is formed in the hole 31 by a blanket W-CVD method. Note that before the W layer is formed by a blanket W-CVD method, a TiN layer/a Ti layer, a TiN layer or a TiW layer can also be formed on the interlayer insulator 30 including the hole 31 by a sputtering method.

Simultaneously with the formation of the hole 31, a hole 31A reaching the conductor pattern 15A is formed in the second interlayer insulator 30 and the first interlayer insulators 18 and 19. Also, a contact plug 32A made of W is formed in the hole 31A at the same time the contact plug 32 is formed. The conductor pattern 15A and an interconnecting line 33 are electrically connected via this contact plug 32A.

[Step-170]

Thereafter, as shown in FIG. 5, an interconnecting line material layer made of an Al-based alloy is formed by a sputtering method on the entire surface of the interlayer insulator 30 including the contact plug 32. Subsequently, photolithography and dry etching are used to pattern the interconnecting line material layer to complete the interconnecting lines 33. Examples of the sputtering conditions of the interconnecting line material layer are as follows.

| | |
|---|---|
| Target | Al = 0.5% Cu |
| Process gas | Ar = 100 sccm |
| Pressure | 0.4 Pa |
| DC power | 5 kw |
| Substrate heating temperature | 300° C. |

In some instances, the interconnecting line material layer can also be buried in the hole 31 without forming the contact plug 32 made of W in the hole 31. If this is the case, to reliably bury the interconnecting line material layer in the hole 31, a Ti layer or the like for improving the wettability is formed on the interlayer insulator 30 including the hole 31. Thereafter, a contact plug made of an Al-based alloy can be formed in the second hole 31 by using any of, e.g., a so-called high-temperature Al sputtering method (in which the substrate heating temperature is set at around 500° C. in the aforementioned sputtering conditions to fluidize the Al-based alloy deposited on the interlayer insulator 30, thereby burying the Al-based alloy in the hole 31), an Al reflow method (in which the substrate heating temperature is set at around 150° C. in the aforementioned sputtering conditions, and after an Al-based alloy is deposited on the interlayer insulator 30, the substrate is heated to around 500° C. to fluidize the Al-based alloy on the interlayer insulator 30, thereby burying the Al-based alloy in the hole 31), and a high-pressure reflow method (in which after an Al-based alloy is deposited on the interlayer insulator 30 in the Al reflow method described above, the substrate is heated in a high-pressure ambient of about 10⁶ Pa to fluidize the Al-based alloy on the interlayer insulator 30 at a high pressure, thereby burying the Al-based alloy in the hole 31).

As described above, the interconnecting line material layer can be buried in the hole 31 without forming the contact plug 32 made of W in the hole 31. This also applies to the embodiments described below. Thereafter, well-known steps are executed to complete the semiconductor device of the first embodiment.

(Second Embodiment)

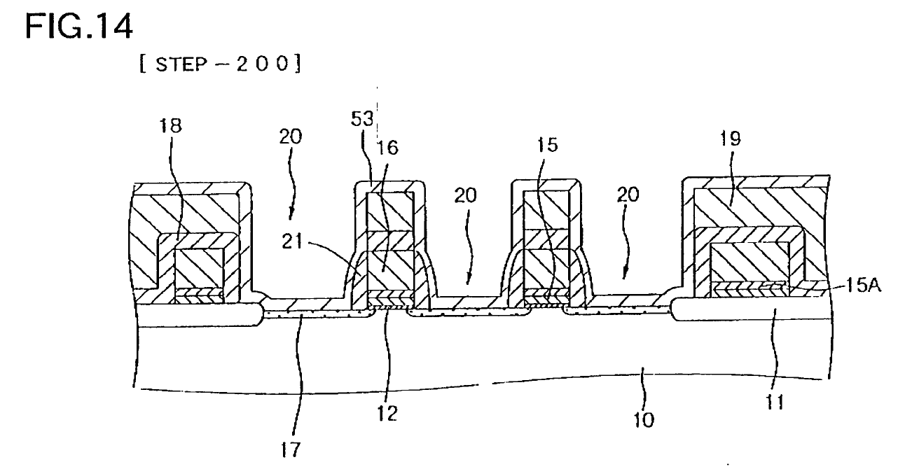

FIGS. 14 to 16 show a part of the second embodiment. This second embodiment is a modification of the above first embodiment. A semiconductor device of the second embodiment differs from the semiconductor device of the first embodiment in that a conductive material filling layer has a three-layered structure including a polysilicon layer 53 containing an impurity, an undercoating layer 54 consisting of at least one of a metal and a metal compound, and a conductive material layer 55.

A method of fabricating the semiconductor device of the second embodiment is the first aspect of the first semiconductor device fabrication method according to the present invention. The semiconductor device fabrication method of the second embodiment differs from the semiconductor device fabrication method of the first embodiment in that the step of forming the conductive material filling layer in first holes 20 comprises the steps of forming the polysilicon layer 53 on first interlayer insulators 18 and 19 including the first holes 20, doping an impurity into the polysilicon layer 53, sequentially forming the undercoating layer 54 consisting of at least one of a metal and a metal compound and the conductive material layer 55 on the polysilicon layer 53, and removing the conductive material layer 55, the undercoating layer 54 and the polysilicon layer 53 on the first interlayer insulator 19.

In this second embodiment, the steps until the first holes 20 are formed can be substantially the same as [step-100] to [step-140] in the first embodiment. Therefore, the steps after the first holes 20 are formed will be described below with reference to FIGS. 14 to 16.

[Step-200]

As shown in FIG. 14, following the formation of the first holes 20 in [step-140] of the first embodiment, a polysilicon layer 53 several tens of nm thick is formed on first interlayer insulators 18 and 19 including the holes 20 by a CVD method. Consequently, the top surface of the insulator 19, the side surfaces of the insulators 18 and 19, the surface of a semiconductor substrate 10 exposed in the bottom portions of the holes 20, and gate side walls 21 are covered with the polysilicon layer 53.

[Step-210]

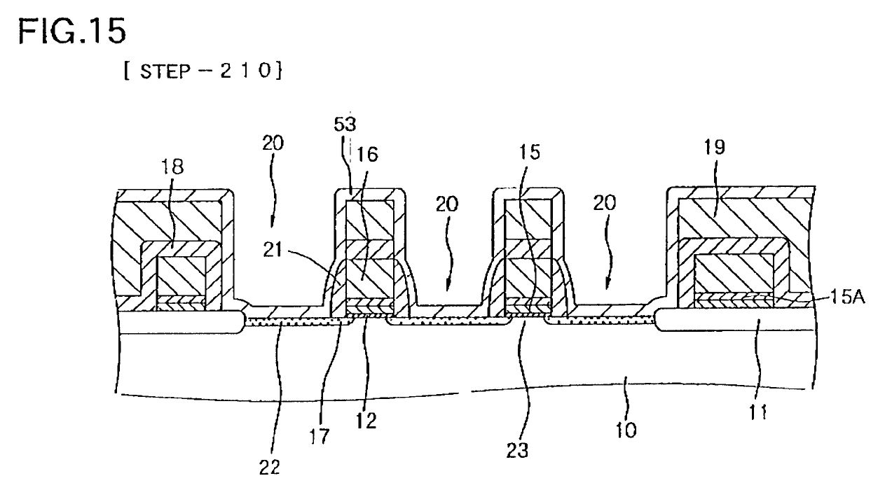

Thereafter, as shown in FIG. 15, an impurity is doped into the polysilicon layer 53 and the underlying semiconductor substrate 10 to form source•drain regions 22 as heavily doped diffusion regions in the semiconductor substrate 10. This step can be substantially the same as the ion implantation in [step-140] of the first embodiment.

[Step-220]

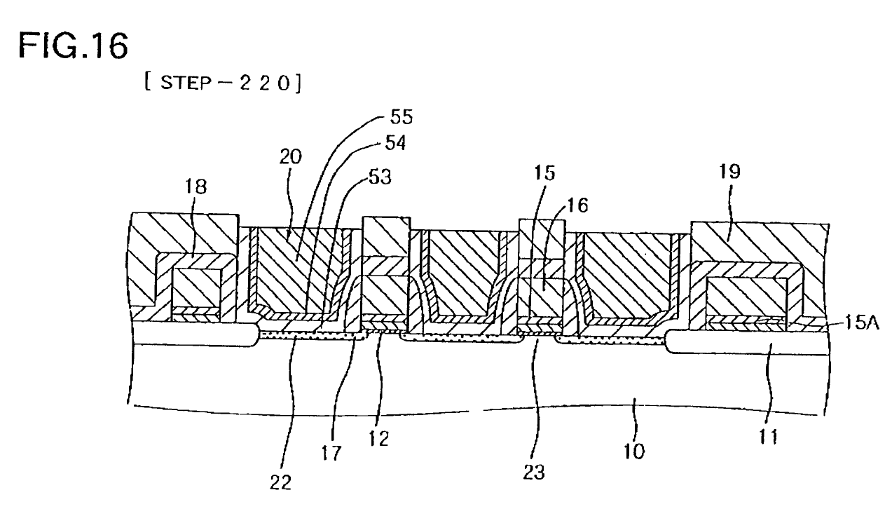

Next, as shown in FIG. 16, an undercoating layer 54 made of Ti and TiN and a conductive material layer 55 made of W are formed in this order on the impurity-doped polysilicon layer 53. Thereafter, the conductive material layer 55, the undercoating layer 54 and the polysilicon layer 53 on the first interlayer insulators 18 and 19 are removed by an etching back method or a CMP method. This step can be substantially the same as [step-150] in the first embodiment. Consequently, a conductive material filling layer having a three-layered structure including the polysilicon layer 53 containing an impurity, the undercoating layer 54 consisting of at least one of a metal and a metal compound, and the conductive material layer 55 is formed in the holes 20.

[Step-230]

Finally, [step-160] and [step-170] of the first embodiment are executed to form a contact plug 32 in a second hole 31 and form interconnecting lines 33 to complete the semiconductor device of this second embodiment.

In the second embodiment as described above, the source•drain regions as heavily doped diffusion regions are formed by ion-implanting an impurity via the polysilicon layer 53. Accordingly, the source•drain regions 22 can be made shallower by the thickness of the polysilicon layer 53 and therefore can be formed in lightly doped diffusion regions 17. Consequently, it is possible to reduce the junction capacitance and increase the junction breakdown voltage. Additionally, the short-channel effect in particularly a P-type MOS transistor can be effectively suppressed.

(Third Embodiment)

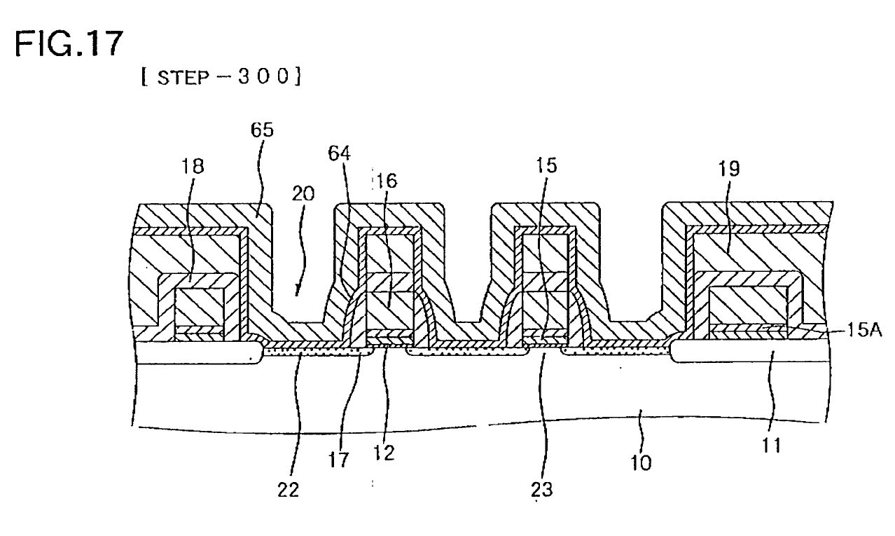

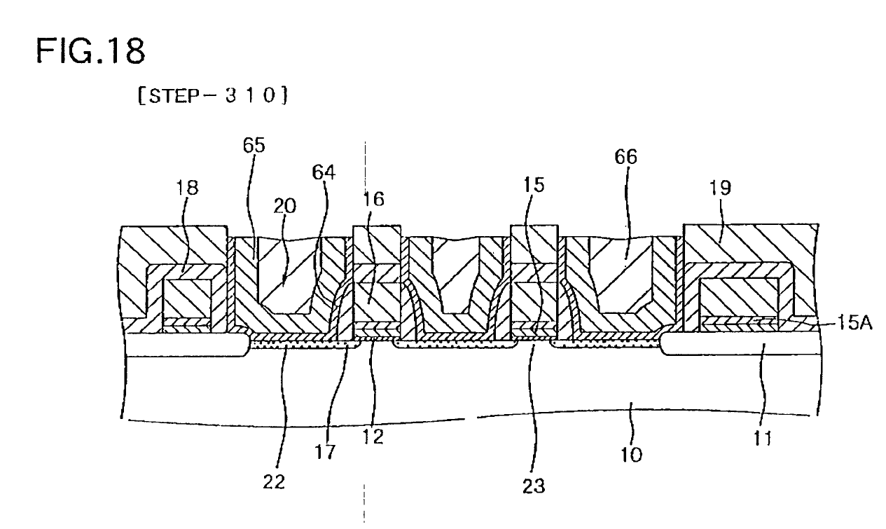

FIGS. 17 and 18 show a part of the third embodiment. This third embodiment is also a modification of the above first embodiment. A semiconductor device of the third embodiment differs from the semiconductor device of the first embodiment in that a conductive material filling layer has a three-layered structure including an undercoating layer 64 made of Ti and TiN, a conductive material layer 65 made of W, and an insulating material layer 66.

A method of fabricating the semiconductor device of the third embodiment is the third aspect of the first semiconductor device fabrication method of the present invention. The semiconductor device fabrication method of the third embodiment differs from the semiconductor device fabrication method of the first embodiment in that the step of forming the conductive material filling layer in first holes 20 comprises the steps of forming the undercoating layer 64 made of Ti and TiN on first interlayer insulators 18 and 19 including the first holes 20, forming the conductive material layer 65 made of W on the undercoating layer 64, forming the insulating material layer 66 on the conductive material layer 65, and removing the insulating material layer 66, the conductive material layer 65 end the undercoating layer 64 on the first interlayer insulator 19. In the third embodiment, the first hole 20 is not completely filled with the W layer. That is, the W layer is so formed as to form a recess in the W layer in the first hole 20, and this recess is filled with the insulating material layer 66.

In the third embodiment, the steps until source•drain regions 22 are formed in a semiconductor substrate 10 exposed in the bottom portions of the first holes 20 can be substantially the same as [step-100] to [step-140] in the first embodiment, Therefore, the steps after the source•drain regions 22 are formed will be described below with reference to FIGS. 17 and 18.

[Step-300]

As shown in FIG. 17, following the formation of the source•drain regions 22 in [step-140] of the first embodiment, an undercoating layer 64 is formed by forming a Ti layer and a TiN layer in this order by a sputtering method on first interlayer insulators 18 and 19 including the holes 20 following the same procedure as in [step-150] of the first embodiment. Thereafter, a W layer is formed on the undercoating layer 64 by a blanket W-CVD method under the same conditions as in [step-150] of the first embodiment. In the third embodiment, the W layer has a thickness of several tens of nm and is so formed that the hole 20 is not completely filled with the W layer and a recess is formed. Consequently, a conductive material layer 65 made of W is formed on the first interlayer insulators 18 and 19 and the side surfaces and the bottoms of the holes 20.

[Step-310]

Thereafter, as shown in FIG. 18, an atmospheric pressure CVD method using O₃+TEOS as materials is performed to deposit an insulating material layer 66, which is an SiO₂ film not containing an impurity and has a thickness of several hundred nm, on the conductive material layer 65 on the first interlayer insulators 18 and 19 including the recesses formed in the conductive material layer 65 in the holes 20. This insulating material layer 66 as an SiO₂ film can also be formed by a bias ECR-CVD method or an SOG coating. Thereafter, the insulating material layer 66, the conductive material layer 65 and the undercoating layer 64 on the first interlayer insulators 18 and 19 are removed by an etching back method or a CMP method.

[Step-320]

Thereafter, [step-160] and [step-170] in the first embodiment are executed to form a contact plug 32 in a second hole 31 and form interconnecting lines 33 to complete the semiconductor device of the third embodiment.

In the third embodiment as described above, the conductive material filling layer has a three-layered structure including the undercoating layer 64 consisting of at least one of a metal and a metal compound, the conductive material layer 65 and the insulating material layer 66. Therefore, the first holes 20 need not be completely filled with the conductive material layer whose step coverage is not so good. As a consequence, the conductive material layer 65 does not apply any large stress to the semiconductor substrate 10.

(Fourth Embodiment)

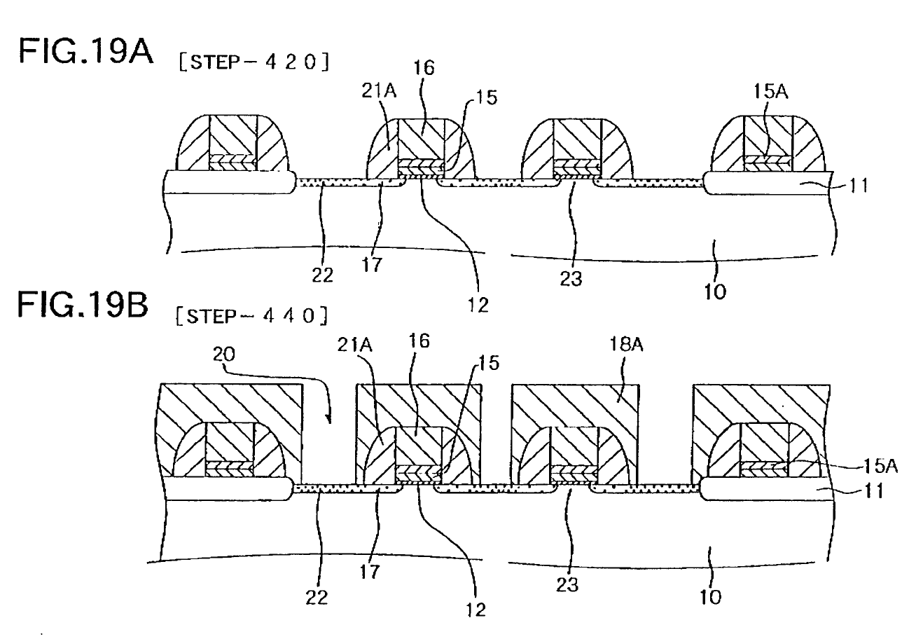

FIGS. 19A to 23 show the fourth embodiment. A method of fabricating a semiconductor device of this fourth embodiment is the first aspect of a second semiconductor device fabrication method according to the present invention. That is, the step of forming a conductive material filling layer in first holes comprises the steps of forming an undercoating layer consisting of at least one of a metal and a metal compound on a first interlayer insulator including the first holes, forming a conductive material layer on this undercoating layer, and removing the conductive material layer and the undercoating layer on the first interlayer insulator.

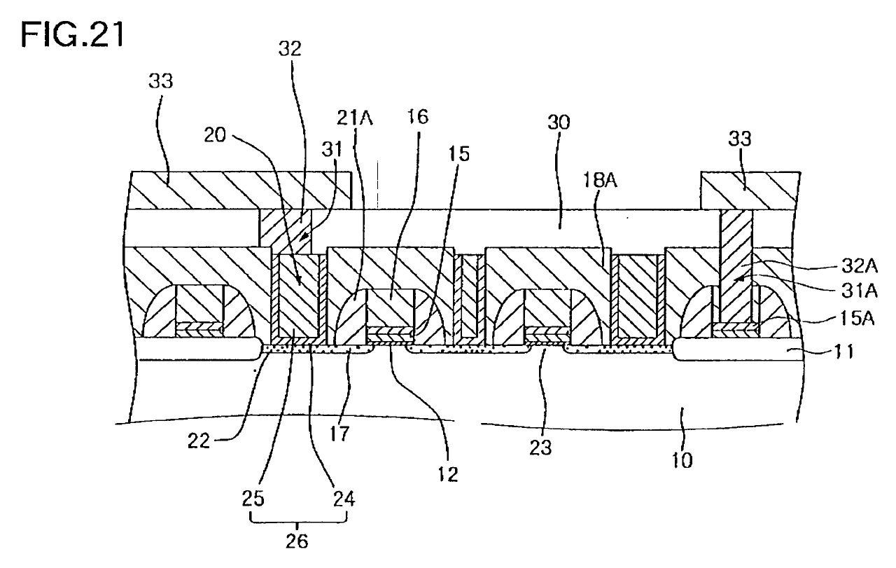

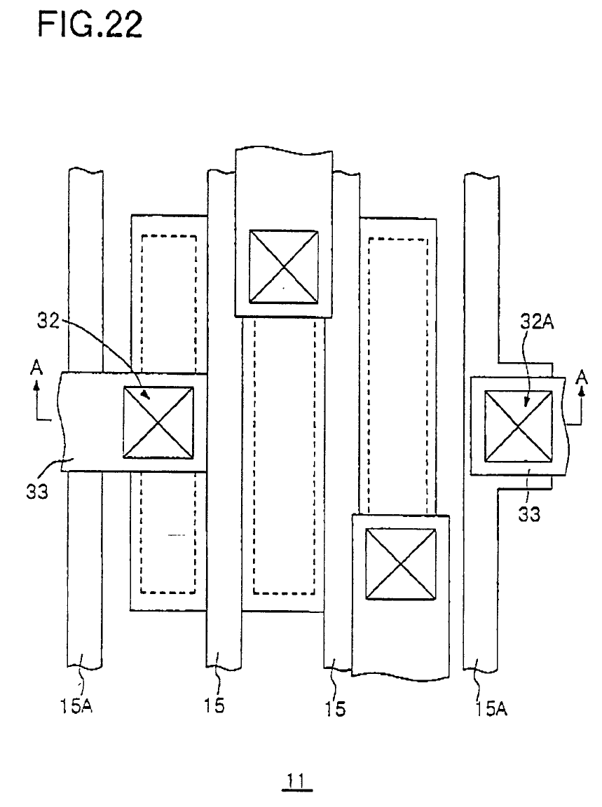

As shown in FIGS. 21 and 22, the semiconductor device of this fourth embodiment has substantially the same structure as the semiconductor device of the first embodiment. That is, the semiconductor device of the fourth embodiment comprises a transistor element, a first interlayer insulator 18A formed on the transistor element, a second interlayer insulator 30 formed on the first interlayer insulator 18A, and interconnecting lines 33 formed on the second interlayer insulator 30 and made of an Al-based alloy. The transistor element has source•drain regions 22, channel regions 23 and gate electrodes 15 formed on a semiconductor substrate 10.

The semiconductor device of the fourth embodiment further comprises a conductive material filling layer 26 formed by burying a conductive material in the first holes 20 formed in the first interlayer insulator 18A on the source•drain regions 22, and contact plugs 32 which are formed in second holes 31 formed in the second interlayer insulator 30 and connect the conductive material filling layer 26 to the interconnecting lines 33.

The first interlayer insulator 18A is a BPSG film, the contact plugs 32 are made of W, and the second interlayer insulator 30 is an SiO₂ film. Note that the conductive material filling layer 26 is also formed on the source•drain region 22 where the contact plug 32 need not be formed. The conductive material filling layer 26 has a two-layered structure including an undercoating layer 24 which also has a two-layered structure including a metal (more specifically, Ti) and a metal compound (more specifically, TiN), and a conductive material layer 25 (more specifically, a W layer).

In the semiconductor device of the fourth embodiment, as in the first embodiment, a conductor pattern 15A formed on an isolation region 11 and extending from the gate electrode of another transistor element is electrically connected to the interconnecting line 33 formed on the second interlayer insulator 30 via a contact plug 32A formed in a hole 31A, which is formed in the first interlayer insulator 18A and the second interlayer insulator 30, and made of W.

The method of fabricating the semiconductor device of the fourth embodiment will be described below with reference to FIGS. 19A to 23. This semiconductor device comprises a CMOS transistor having an N-type MOS transistor and a P-type MOS transistor, however, FIGS. 19A to 23 show one of these MOS transistors and its fabrication steps. Also, FIGS. 19A to 21 are side sectional views taken along a line A-A in FIG. 22.

[Step-400]

First, as shown in FIG. 19A, an isolation region 11 and an active region surrounded by this isolation region 11 are formed on a semiconductor substrate 10 as an Si substrate by a well-known method as in [step-100] of the first embodiment.

[Step-410]

Next, as in [step-110] of the first embodiment, gate electrodes 15 made of a W silicide layer 14 and a polysilicon layer 13 are formed on the semiconductor substrate 10, and conductor patterns 15A made of the W silicide layer 14 and the polysilicon layer 13 are also formed in the isolation region 11.

[Step-420]

Thereafter, as in [step-120] of the first embodiment, lightly doped diffusion regions 17 are formed in an N-type MOS transistor formation region and a P-type MOS transistor formation region. Subsequently, an SiO₂ layer is formed on the entire surface and etched back to form so-called gate side walls 21A on the side surfaces of the gate electrodes 15. Following the same procedure as in [step-140] of the first embodiment, ion implantation and activation are performed to form source•drain regions 22 as heavily doped diffusion regions and channel regions 23.

[Step-430]

Next, as shown in FIG. 19B, a first interlayer insulator 18A which is, e.g., a BPSG film and has a thickness of several hundred nm is deposited on the entire surface by a CVD method. The surface of this interlayer insulator 18A is planarized by performing reflow at 800 to 900° C.

[Step-440]

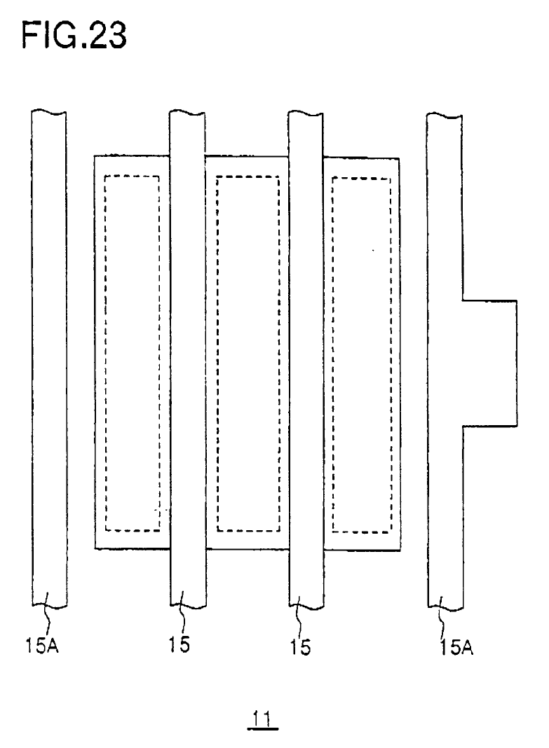

The surface of the interlayer insulator 18A is coated with a resist, and the resist is patterned, as shown in FIG. 23, so as to expose, for example, 50% or more of the source•drain regions 22. Referring to FIG. 23, the patterns of first holes corresponding to the hole patterns of the resist are indicated by the dotted lines. C₄F₈/CO-based etching gas is used to anisotropically etch the interlayer insulator 18A to form first holes 20 in the interlayer insulator 18A.

[Step-450]

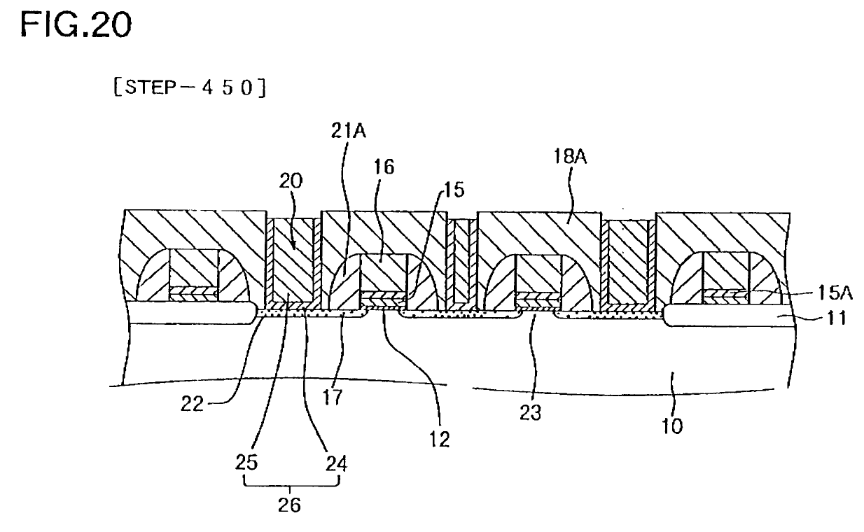

Thereafter, as shown in FIG. 20, an undercoating layer 24 consisting of at least one of Ti and TiN is formed on the first interlayer insulator 18A including the first holes 20, and a conductive material layer 25 made of W is formed on this undercoating layer 24. Subsequently, the conductive material layer 25 and the undercoating layer 24 on the interlayer insulator 18A are removed by an etching back method to form a conductive material filling layer 26 in the holes 20. This step can be the same as [step-150] in the first embodiment, so a detailed description thereof will be omitted.

[Step-460]

Next, as shown in FIG. 21, a second interlayer insulator 30 is formed on the first interlayer insulator 18A including the conductive material filling layer 26. A second hole 31 is formed in the interlayer insulator 30 above the conductive material filling layer 30. Subsequently, the hole 31 is filled with a conductive material to form a contact plug 32 in this hole 31. More specifically, this step can be the same as [step-160] in the first embodiment.

Note that in this fourth embodiment, as in the first embodiment, a hole 31A and a contact plug 32A can be formed following the same procedure as and simultaneously with the formation of the hole 31 and the contact plug 32.

[Step-470]

Thereafter, as in [step-170] of the first embodiment, an interconnecting line material layer made of an Al-based alloy is formed by a sputtering method on the entire surface of the interlayer insulator 30 including the contact plug 32. Subsequently, photolithography and dry etching are used to pattern the interconnecting line material layer to form interconnecting lines 33. Finally, well-known steps are executed to complete the semiconductor device of this fourth embodiment.

(Fifth Embodiment)

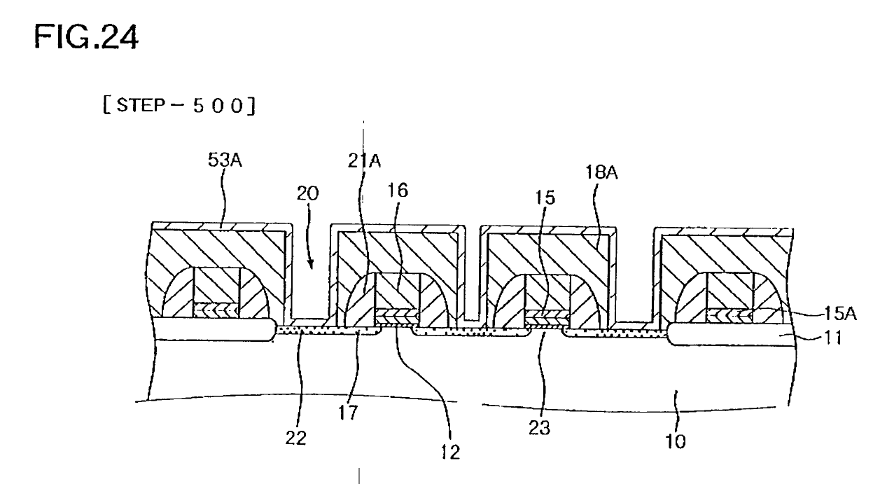

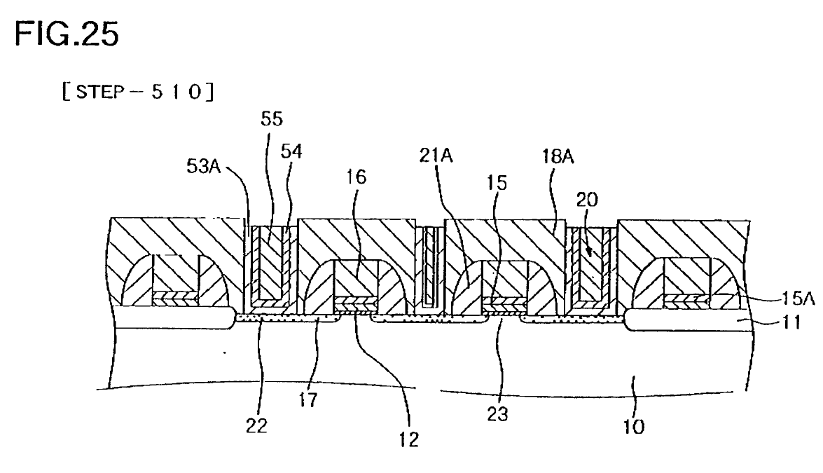

FIGS. 24 and 25 show the fifth embodiment. This fifth embodiment is a modification of the above fourth embodiment. A semiconductor device of the fifth embodiment differs from the semiconductor device of the fourth embodiment in that a conductive material filling layer has a three-layered structure including a polysilicon layer 53A containing an impurity, an undercoating layer 54 consisting of at least one of a metal and a metal compound, and a conductive material layer 55.

A method of fabricating the semiconductor device of the fifth embodiment is the second aspect of the second semiconductor device fabrication method according to the present invention. The semiconductor device fabrication method of the fifth embodiment differs from the semiconductor device fabrication method of the fourth embodiment in that the step of forming the conductive material filling layer in first holes 20 comprises the steps of forming the polysilicon layer 53A containing an impurity on a first interlayer insulator 18A including the first holes 20, sequentially forming the undercoating layer 54 consisting of at least one of a metal and a metal compound and the conductive material layer 55 on the polysilicon layer 53A, and removing the conductive material layer 55, the undercoating layer 54 and the polysilicon layer 53A on the first interlayer insulator 18A.

In this fifth embodiment, the steps until the first holes 20 are formed can be the same as [step-400] to [step-440] in the fourth embodiment. Therefore, the steps after the first holes 20 are formed will be described below with reference to FIGS. 24 and 25.

[Step-500]

As shown in FIG. 24, following the formation of the first holes 20 in [step-440] of the fourth embodiment, a polysilicon layer 53A several tens of nm thick containing an impurity is formed on a first interlayer insulator 18A including the holes 20 by a CVD method as in [step-200] of the second embodiment. Consequently, the top surface of the interlayer insulator 18A, the side surfaces of the holes 20, and the surface of a semiconductor substrate 10 exposed in the bottom portions of the holes 20 are covered with the polysilicon layer 53A.

[Step-510]

Next, as shown in FIG. 25, an undercoating layer 54 made of Ti and TiN and a conductive material layer 55 made of W are formed in this order on the polysilicon layer 53A. Thereafter, the conductive material layer 55, the undercoating layer 54 and the polysilicon layer 53A on the interlayer insulator 18A are removed by an etching back method or a CMP method. This step can be substantially the same as [step-150] in the first embodiment. Consequently, a conductive material filling layer having a three-layered structure including the polysilicon layer 53A containing an impurity, the undercoating layer 54 consisting of at least one of a metal and a metal compound, and the conductive material layer 55 is formed in the holes 20.

[Step-523]

Finally, following the same procedures as in [step-460] and [step-470] of the fourth embodiment, a contact plug 32 is formed in a second hole 31 and interconnecting lines 33 are formed to complete the semiconductor device of this fifth embodiment.

(Sixth Embodiment)

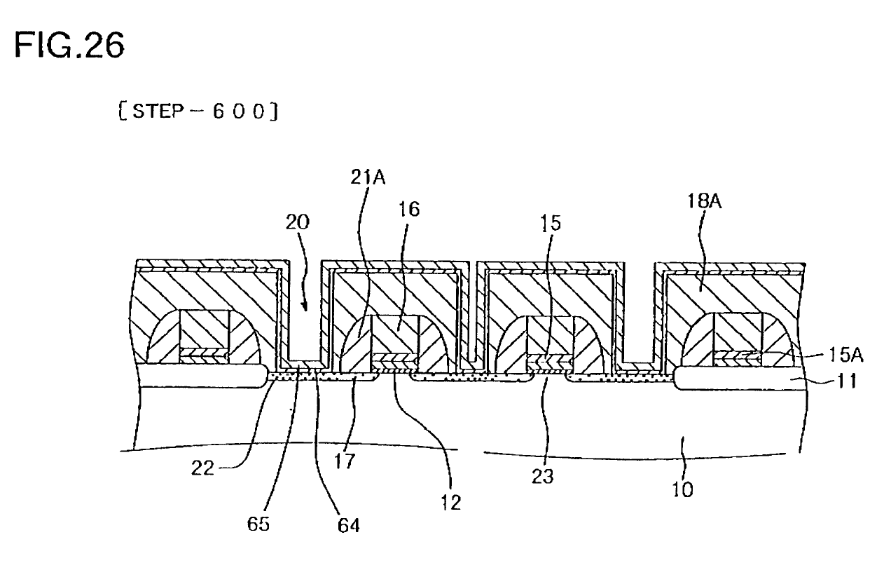

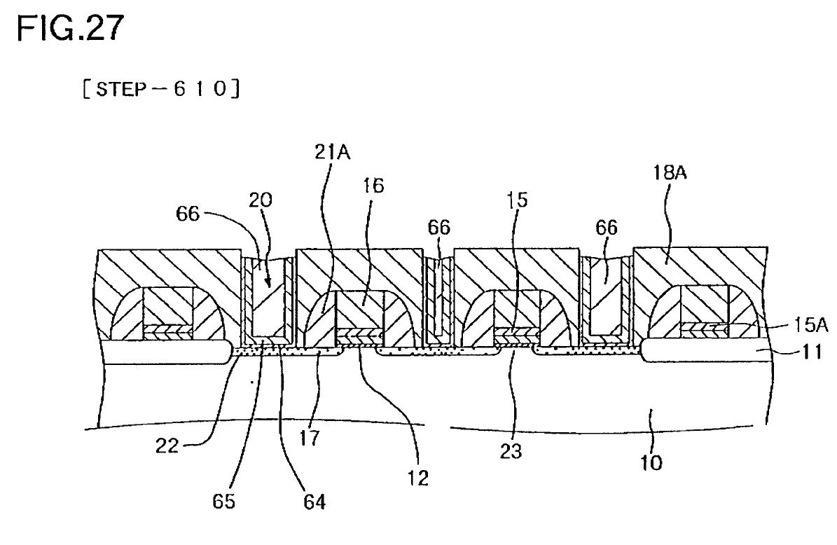

FIGS. 26 and 27 show the sixth embodiment. This sixth embodiment is also a modification of the above fourth embodiment. A semiconductor device of the sixth embodiment differs from the semiconductor device of the fourth embodiment in that a conductive material filling layer has a three-layered structure including an undercoating layer 64 made of Ti and TiN, a conductive material layer 65 made of W, and an insulating material layer 66.

A method of fabricating the semiconductor device of the sixth embodiment is the third aspect of the second semiconductor device fabrication method of the present invention. The semiconductor device fabrication method of the sixth embodiment differs from the semiconductor device fabrication method of the fourth embodiment in that the step of forming the conductive material filling layer in first holes 20 comprises the steps of forming the undercoating layer 64 made of Ti and TiN on a first interlayer insulator 18A including the first holes 20, forming the conductive material layer 65 made of W on the undercoating layer 64, forming the insulating material layer 66 on the conductive material layer 65, and removing the insulating material layer 66, the conductive material layer 65 and the undercoating layer 64 on the first interlayer insulator 18A. In the sixth embodiment, the first hole 20 is not completely filled with the W layer. That is, the W layer is so formed as to form a recess in the W layer in the first hole 20, and this recess is filled with the insulating material layer 66.

In the sixth embodiment, the steps until source•drain regions 22 are formed in a semiconductor substrate 10 exposed in the bottom portions of the first holes 20 can be substantially the same as [step-400] to [step-440] in the fourth embodiment. Therefore, the steps after the source•drain regions 22 are formed will be described below with reference to FIGS. 26 and 27.

[Step-600]

As shown in FIG. 26, following the formation of the source•drain regions 22 in [step-440] of the fourth embodiment, an undercoating layer 64 is formed by forming a Ti layer and a TiN layer in this order by a sputtering method on a first interlayer insulator 18A including the first holes 20 following the same procedure as in [step-150] of the first embodiment. Thereafter, a W layer is formed on the undercoating layer 64 by a blanket W-CVD method under the same conditions as in [step-150] of the first embodiment. In the sixth embodiment, the W layer has a thickness of several tens of nm and is so formed that the hole 20 is not completely filled with the W layer and a recess is formed. Consequently, a conductive material layer 65 made of W is formed on the first interlayer insulator 18A and the side surfaces and the bottoms of the holes 20.

[step-610]

Thereafter, as shown in FIG. 27, a CVD method using O₃+TEOS as materials is performed to deposit an insulating material layer 66, which is an SiO₂ film not containing an impurity and has a thickness of several hundred nm, on the conductive material layer 65. This insulating material layer 66 as an SiO₂ film can also be formed by a bias ECR-CVD method or an SOG coating. Thereafter, the insulating material layer 66, the conductive material layer 65 and the undercoating layer 64 on the first interlayer insulator 18A are removed by an etching back method or a CMP method.

[step-620]

Thereafter, following the same procedures as in [step-460] and [step-470] of the fourth embodiment, a contact plug 32 is formed in a second hole 31 and interconnecting lines 33 are formed to complete the semiconductor device of the sixth embodiment.

In the sixth embodiment as described above. the conductive material filling layer has a three-layered structure including the undercoating layer 64 consisting of at least one of a metal and a metal compound, the conductive material layer 65 and the insulating material layer 66. Therefore, the holes 20 need not be completely filled with the conductive material layer whose step coverage is not so good. As a consequence, the conductive material layer 65 does not apply any large stress to the semiconductor substrate 10.

(Seventh Embodiment)

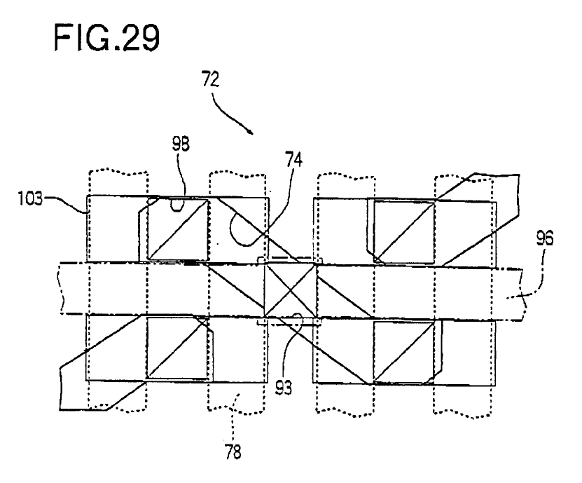

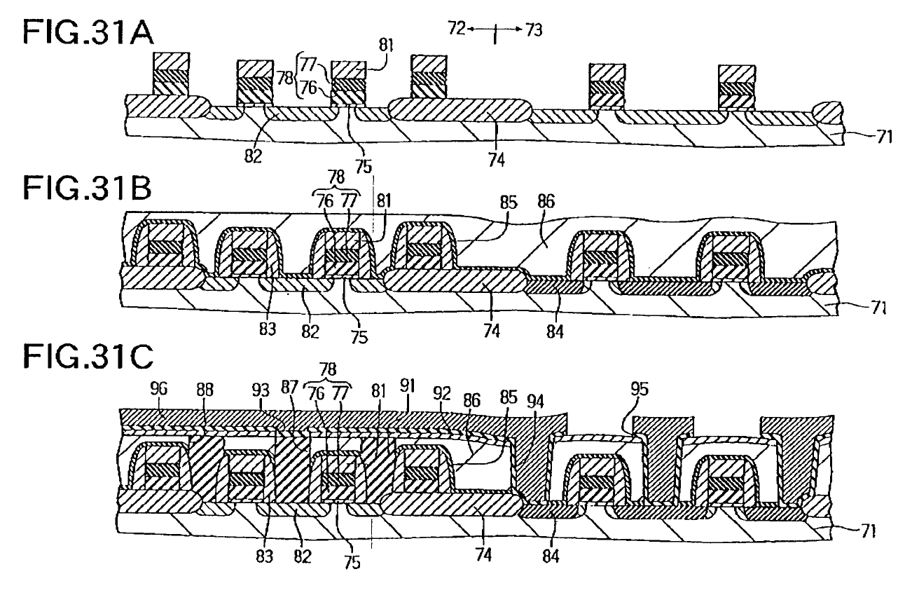

FIGS. 28 to 33 show the seventh embodiment. To fabricate a semiconductor device of this seventh embodiment, as shown in FIGS. 31A and 29, an isolation region is defined by selectively forming an SiO₂ film 74 by, e.g., a LOCOS method on the entire surface of a memory cell region 72, a logic circuit region 73, and a peripheral circuit region (not shown) of an Si substrate 71. An SiO₂ film 75 as a gate oxide film is formed on the surface of the active region surrounded by the SiO₂ film 74.

Thereafter, a polysilicon layer 76 containing an impurity and a WSix layer 77 are sequentially deposited by a CVD method to form a W polycide layer 78, and an SiO₂ film 81 is deposited on the W polycide layer 78 by a CVD method such that their total thickness is several hundred nm. The SiO₂ film 81 and the W polycide layer 78 are processed into the patterns of gate electrodes.

The SiO₂ films 74 and 81, the W polycide layer 78 and the like are used as masks to ion-implant an impurity into the Si substrate 71 to form lightly doped diffusion regions 82. More specifically, As or phosphorus is ion-implanted into an N-type MOS transistor formation region in a dose of 1×10¹² to 1× 10¹⁴ cm⁻² at an acceleration energy of several tens of keV. Also, B or BF₂ is ion-implanted into a P-type MOS transistor formation region in a dose of 1×10¹³ to 1×10¹⁴ cm⁻² at an acceleration energy of 10 to several tens of keV.

Next, as shown in FIG. 31B, an SiO₂ film 83 several tens to a hundred and several tens of nm thick is deposited by a low pressure CVD method using TEOS as a material. The entire surface of the SiO₂ film 83 is etched back to form side-wall spacers made of this SiO₂ film 83 on the side surfaces of the W polycide layer 78 and the SiO₂ film 81.

Thereafter, the SiO₂ films 74, 81, and 83, the W polycide layer 78 and the like are used as masks to ion-implant an impurity into the Si substrate 71 in the logic circuit region 73 and the peripheral circuit region. More specifically, As is ion-implanted into the N-type MOS transistor formation region in a dose of 1×10¹⁵ to 1×10¹⁶ at an acceleration energy of several tens of keV, and B or BF₂ is ion-implanted into the P-type MOS transistor formation region under the same conditions.

An SiN film 85 several tens of nm thick is deposited by a low pressure CVD method, and a BPSG film 86 several hundred nm thick is deposited by a CVD method using O₃+TEOS as materials. The surface of the BPSG film 86 is planarized by reflow or chemical mechanical polishing.

Next, as shown in FIG. 31C, a contact hole 87 for a bit line and contact holes 88 for storage node electrodes reaching the lightly doped diffusion regions 82 in the memory cell region 72 are formed in the BPSG film 86 and the SiN film 85 and filled with polysilicon plugs 91 containing an impurity.

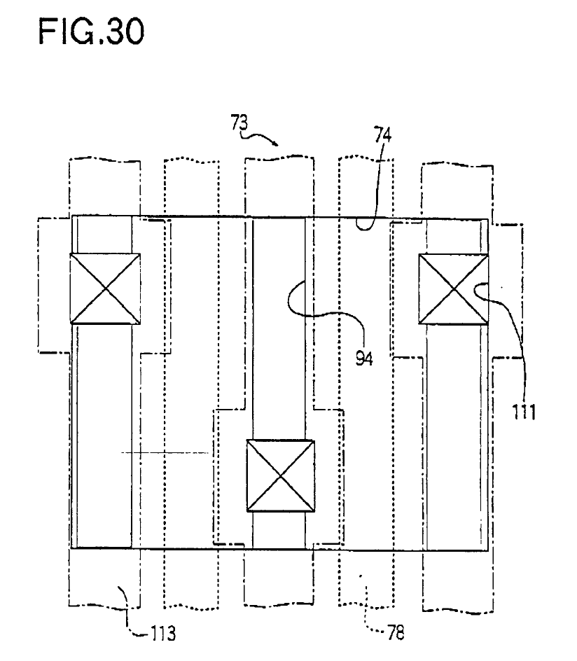

An SiO₂ film 92 several tens of nm thick is deposited, and a contact hole 93 reaching the polysilicon plug 91 in the contact hole 87 is formed in the SiO₂ film 92. Thereafter, as is also shown in FIG. 30, holes 94 having patterns close to the patterns of the heavily doped diffusion regions 84 in the logical circuit region 73 and the peripheral circuit region and reaching these heavily doped diffusion regions 84 are formed in the SiO₂ film 92, the BPSG film 86 and the SiN film 85. Note that an SiN film or the like can also be used instead of the SiO₂ film 92.

A TiN/Ti layer 95 several tens of nm thick serving as a barrier metal layer is deposited by a sputtering method or a CVD method, and a W layer 96 several hundred nm thick is deposited by a CVD method. The W layer 96 and the TiN/Ti layer 95 are processed into a pattern of a bit line and a pattern slightly larger than the hole 94 as is also shown in FIG. 29.

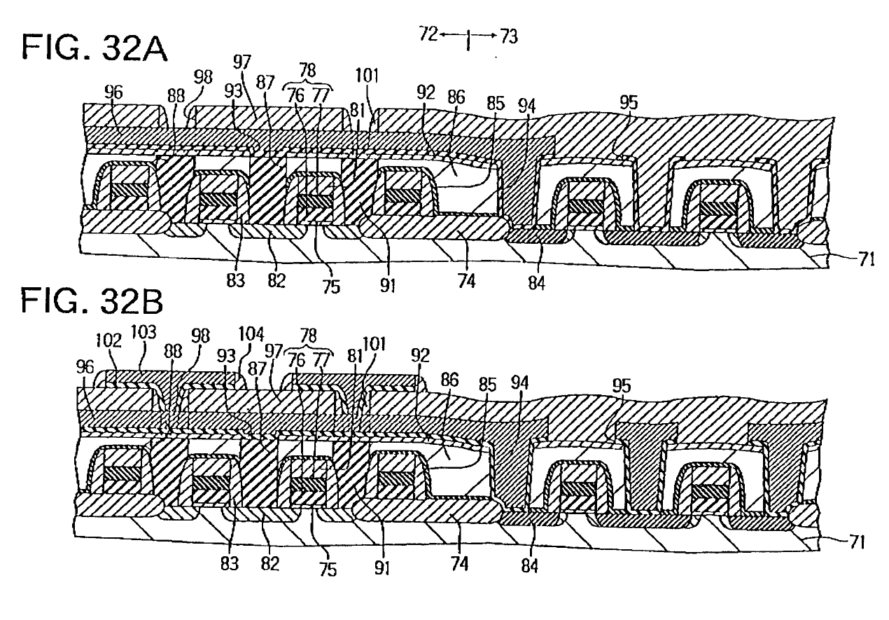

Next, as shown FIGS. 32A and 29, an interlayer insulator 97 several hundred nm thick is deposited by a CVD method, and contact holes 98 reaching the polysilicon plugs 91 in the contact holes 88 are formed in the interlayer insulator 97 and the SiO₂ film 92. An SiO₂ film 101 several hundred nm thick is deposited, and the entire surface of the SiO₂ film 101 is etched back to form side-wall spacers made of this SiO₂ film 101 on the inner side surfaces of the contact holes 98.

As shown in FIG. 32B, a TiN/Ti layer 102 several tens of nm thick is deposited by a CVD method, and a metal-containing layer 103 several tens of nm to several hundred nm thick made of, e.g., W, Pt, Ru, RuO₂, or IrO₂ is deposited by a sputtering method. As is also shown in FIG. 29, the metal-containing layer 103 and the TiN/Ti layer 102 are processed into patterns of the storage node electrodes.

The metal-containing layer 103 and the TiN/Ti layer 102 in the contact holes 98 are dielectrically isolated from the W layer 96 and the TiN/Ti layer 95 as bit lines by the SiO₂ film, 101. Thereafter, an SiO₂ film 104 several hundred nm thick is deposited, and the entire surface of the SiO₂ film is etched back to form side-wall spacers made of this SiO₂ film 104 on the side surfaces of the metal-containing layer 103 and the TiN/Ti layer 102.

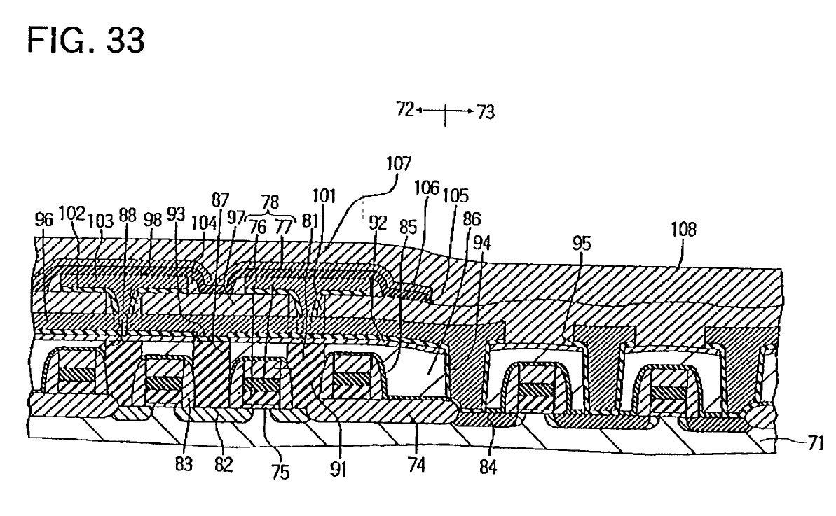

Next, as shown in FIG. 33, a high dielectric film 105 several tens of nm to several hundred nm thick made of, e.g., BST (BaₓSr₁₋ₓTiO₃), STO (SrTiO₃) or Ta₂O₅ is deposited by, e.g., a CVD method or a sputtering method and annealed in an O₃ or O₂ plasma ambient. Since the steps on the metal-containing layer 103 and the TiN/Ti layer 102 are reduced by the SiO₂ film 104, a capacitor leak caused by deterioration of the film quality of the high dielectric film 105 is prevented.

Thereafter, a metal-containing layer 106 several tens of nm thick made of, e.g., TiN, WN, Pt or W is deposited by a sputtering method. The metal-containing layer 106 and the high dielectric film 105 are processed into the pattern of a plate electrode to complete a capacitor 107 constituting a memory cell in the memory cell region 72. An interlayer insulator 108 several hundred nm thick is then deposited by a CVD method.

Next, as shown in FIG. 28, a contact hole 111 reaching the W layer 96 is formed in the interlayer insulators 108 and 97, and a TiN/Ti layer 112 and a W layer 113 by which the contact hole 111 is filled are processed into the pattern of an interconnecting line.

Thereafter, an interlayer insulator 114 is deposited, and a via hole 115 reaching the W layer 113 is formed in the interlayer insulator 114 and filled with a TiN layer 116 and a W plug 117. Finally, a TiN layer 117, an Al layer 121 and a TiN layer 122 connecting with the W plug 117 is processed into the interconnecting line pattern, and a passivation film 123 is deposited to complete the semiconductor device of this seventh embodiment.

(Eighth Embodiment)

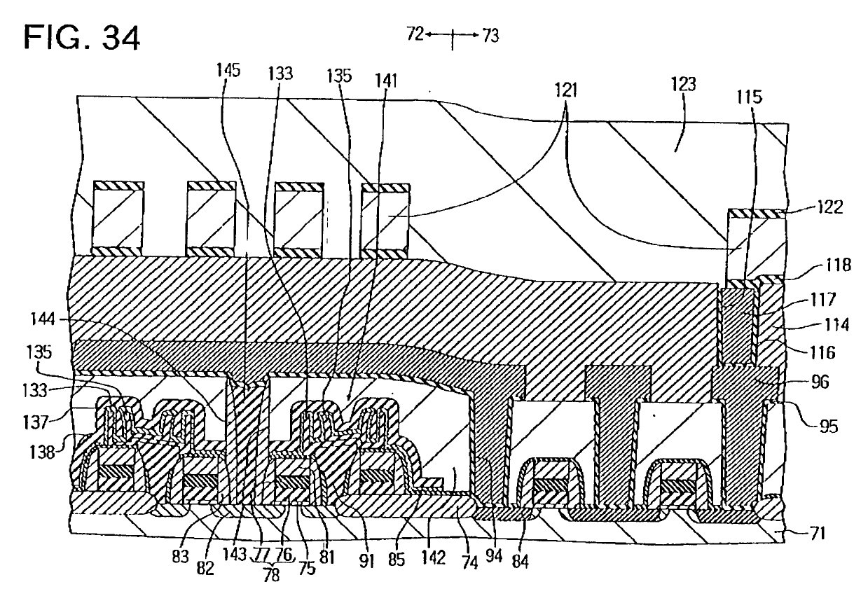

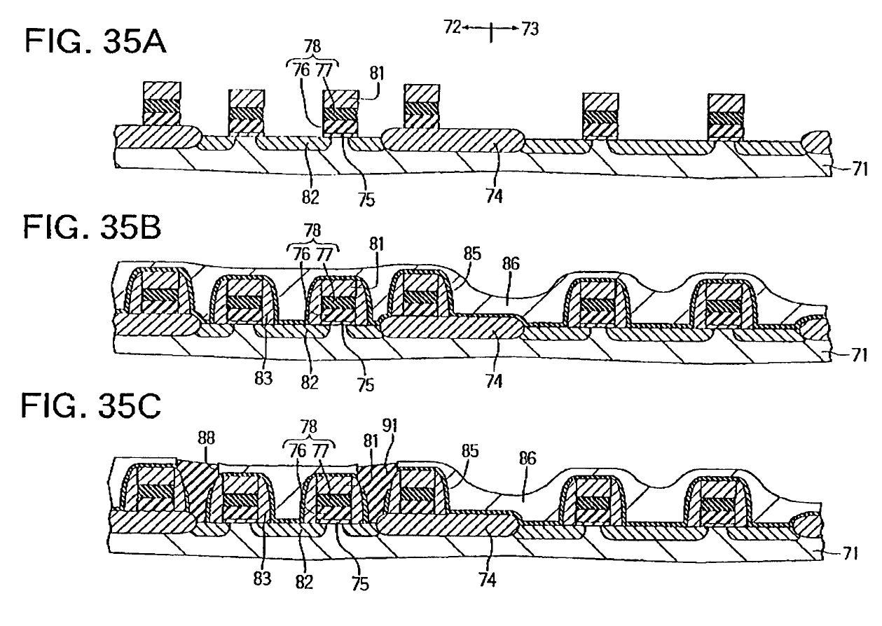

FIGS. 34 to 38B show the eighth embodiment. As shown in FIGS. 35A and 35B, a semiconductor device of this eighth embodiment is also fabricated by executing substantially the same steps as shown in FIGS. 31A and 31B of the above seventh embodiment until the surface of a BPSG film 86 is planarized, except that no heavily doped diffusion layer 84 is formed.

In this eighth embodiment, however, as shown FIG. 35C, contact holes 88 for storage node electrodes reaching lightly doped diffusion regions 82 in a memory cell region 72 are formed in the BPSG film 86 and an SiN film 85 and filled with polysilicon plugs 91 containing an imparity.

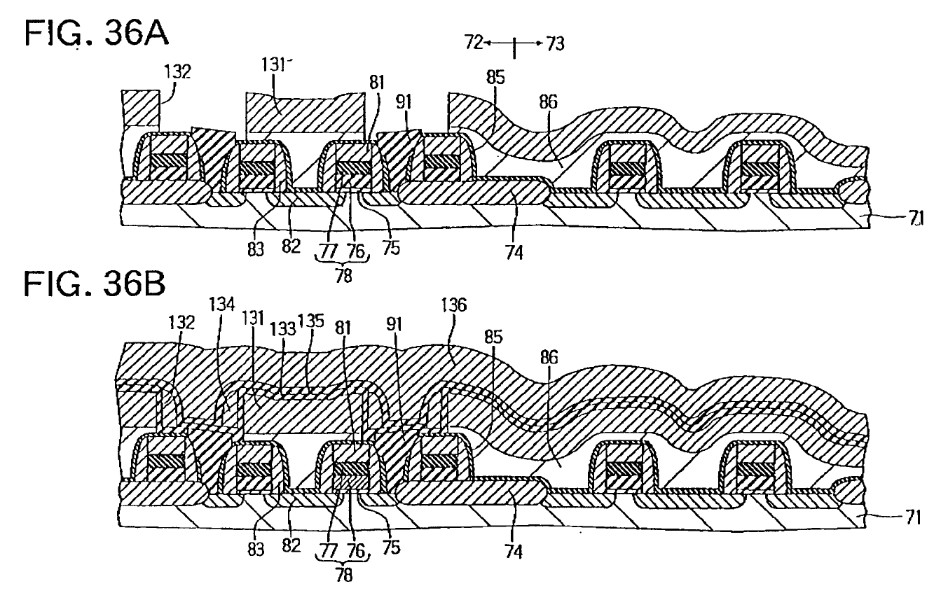

Next, as shown in FIG. 36A, an SiO₂ film 131 several hundred nm thick is deposited by a CVD method. The SiN film 85 is used as a stopper to etch the SiO₂ film 131 and the BPSG film 86 until the polysilicon plugs 91 are exposed, thereby forming recesses 132 corresponding to the patterns of storage node electrodes. Note that a BPSG film can also be used instead of the SiO₂ film 131 containing no impurity.

As shown in FIG. 36B, a polysilicon layer 133 several tens of nm thick containing an impurity and an SiO₂ film 134 several tens of nm thick are sequentially deposited by a CVD method. The entire surface of the SiO₂ film 134 is etched back to form side-wall spacers made of this SiO₂ film 134 on the inner side surfaces of the recesses 132. Again, a polysilicon layer 135 several tens of nm thick containing an impurity and an SiO₂ film 136 several hundred nm thick are sequentially deposited by a CVD method.

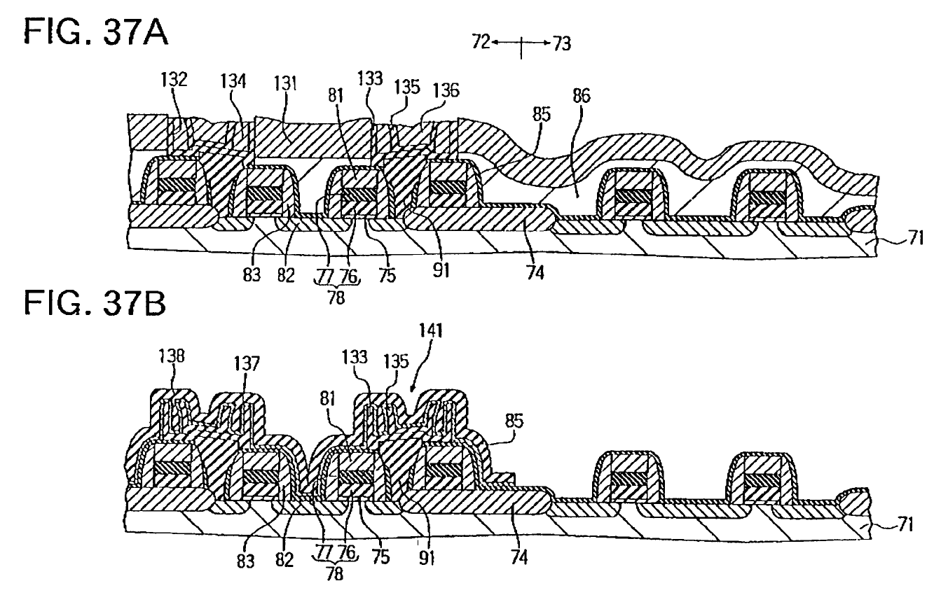

Next, as shown in FIG. 37A, the SiO₂ film 136 and the polysilicon layers 135 and 133 are sequentially etched back until the SiO₂ film 134 is exposed. Thereafter, as shown in FIG. 37B, the residual SiO₂ films 121, 134, and 136 and BPSG film 86 are removed by an etching solution containing hydrofluoric acid.

A dielectric film 137 such as an ONO film and a polysilicon layer 138 several tens to a hundred and several tens of nm thick containing an impurity are sequentially deposited by a CVD method. These polysilicon layer 138 and dielectric film 137 are then processed into the pattern of a plate electrode to complete a capacitor 141 constituting the memory cell in the memory cell region 72.

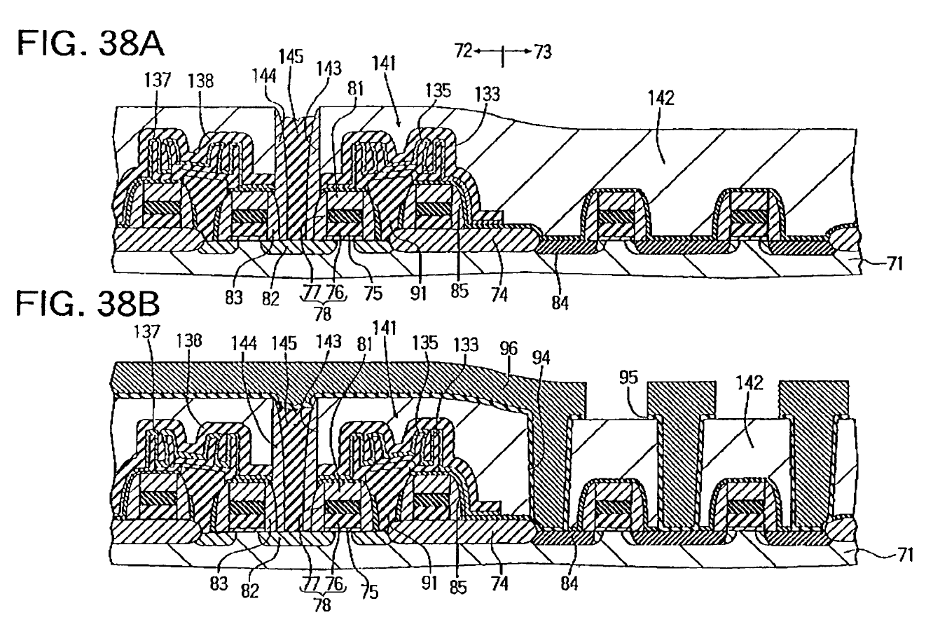

Subsequently, as shown in FIG. 38A, the SiO₂ films 74, 81, and 83, the W polycide layer 78 and the like are used as masks to ion-implant an impurity into an Si substrate 71 in a logic circuit region 73 and a peripheral circuit region to form heavily doped diffusion regions 84. More specifically, As is ion-implanted into an N-type MOS transistor formation region in a dose of 1×10¹⁵ to 1×10¹⁶ cm⁻² at an acceleration energy of several tens of keV, and B or BF₂ is ion-implanted into a P-type MOS transistor formation region under the same conditions.

Thereafter, a BPSG film 142 several hundred nm thick is deposited by a CVD method, and the surface of this BPSG film 142 is planarized with reflow by an annealing at 800 to 900° C. in a nitrogen ambient. A contact hole 143 for a bit line reaching the lightly doped diffusion layer 82 in the memory cell region 72 is formed in the BPSG film 142, the polysilicon layer 138, the dielectric film 137 and the SiN film 85.

Side-wall spacers made of an SiO₂ film 144 are formed on the inner side surfaces of the contact hole 143, and the contact hole 143 is filled with a polysilicon plug 145 containing an impurity. Accordingly, the polysilicon layer 138 as a plate electrode and the polysilicon plug 145 are dielectrically isolated by the SiO₂ film 144.

Next, as shown in FIG. 38B, holes 94 having patterns close to the patterns of the heavily doped diffusion regions 84 in the logical circuit region 73 and the peripheral circuit region and reaching these heavily doped diffusion regions 84 are formed in the BPSG film 142 and the SiN film 85. Thereafter, a TiN/Ti layer 95 several tens of nm thick serving as a barrier metal layer is deposited by a sputtering method or a CVD method, and a W layer 96 several hundred nm thick is deposited by a CVD method. The W layer 96 and the TiN/Ti layer 95 are processed into a pattern of a bit line and a pattern slightly larger than the hole 94.

As shown in FIG. 34, an interlayer insulator 114 is deposited, and a via hole 115 reaching the W layer 96 is formed in the interlayer insulator 114 and filled with a TiN layer 116 and a W plug 117. Finally, a TiN layer 118, an Al layer 121 and a TiN layer 122 connecting with the W plug 117 is processed into the pattern of an interconnecting line, and a passivation film 123 is deposited to complete the semiconductor device of this eighth embodiment.

(Ninth Embodiment)

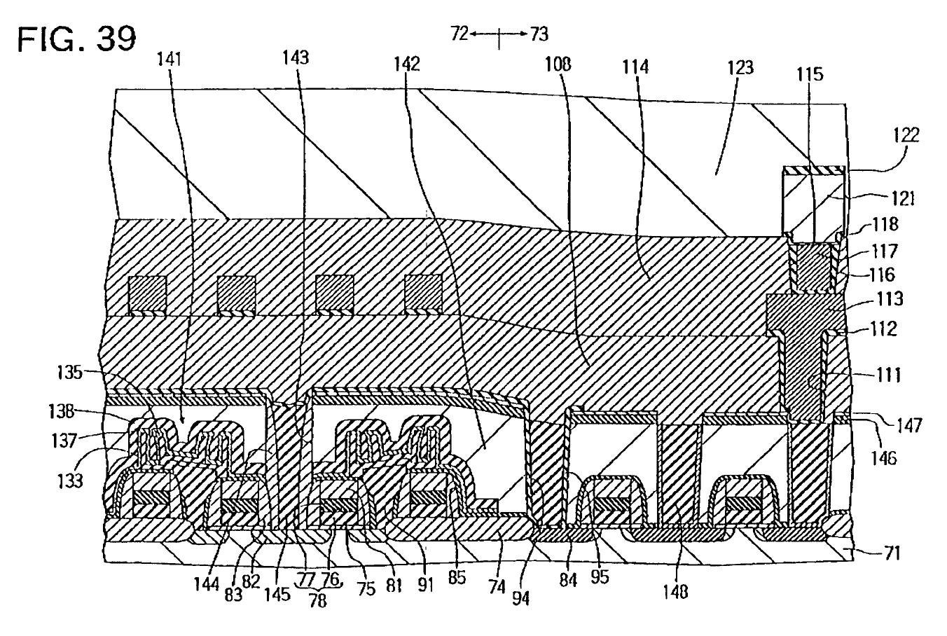

FIG. 39 shows the ninth embodiment. In a semiconductor device of this ninth embodiment, an SiN film 146 and an SiO₂ film 147 are sequentially stacked on a BPSG film 142. Holes 94 in a logic circuit region 73 are filled with a TiN/Ti layer 95 and W plugs 148, and the TiN/Ti layer 95 alone forms bit lines. Except for these differences, the semiconductor device of the ninth embodiment has substantially the same structure as the eight embodiment shown in FIG. 34 in a portion below the bit lines and substantially the same structure as the seventh embodiment shown in FIG. 28 in a portion above the bit lines.

Although the present invention has been described on the basis of its preferred embodiments, the present invention is not limited to these embodiments. The conditions, numerical values, materials and semiconductor device structures explained in the embodiments are merely examples and can be appropriately changed.

In the above embodiments, a conductive material layer is formed exclusively by a blanket W-CVD method. However, the material of the conductive material layer is not limited to W, and various metals and refractory metals can be used. For example, a conductive material layer made of Cu or Al can be formed in the first hole 20 by forming a Cu layer or an Al layer by a CVD method. The conditions under which the Cu layer is formed by a CVD method are as follows. Note that HFA is the abbreviation for hexafluoroacetylacetonate.

CVD formation conditions of Cu

| | |
|---|---|
| Gases used | Cu(HFA)₂/H₂ = 10/1000 sccm |
| Pressure | 2.6 × 10³ Pa |
| Substrate heating temperature | 350° C. |
| Power | 500 W |

Also, in the above embodiments a TiN layer and a Ti layer are formed by a sputtering method. However, the TiN and Ti layers can also be formed by a CVD method, instead of a sputtering method, under the following conditions. ECR-CVD conditions of Ti

| | |
|---|---|
| Gases used | TiCl₄/H₂ = 10/50 sccm |
| Microwave power | 2.18 kW |
| Temperature | 420° C. |
| Pressure | 0.12 Pa |

ECR-CVD conditions of TiN

| | |
|---|---|
| Gases used | TiCl₄/H₂/N₂ = 20/26/8 sccm |
| Microwave power | 2.8 kW |
| Substrate RF bias | −50 W |
| Temperature | 420° C. |
| Pressure | 0.12 Pa |

In the above embodiments, Al—Cu is used as an Al-based alloy for forming interconnecting lines. However, it is also possible to use pure Al and various Al alloys, such as Al—Si, Al—Si—Cu, Al—Ge and Al—Si—Ge, instead of Al—Cu.

In the third and sixth embodiments, a conductive material filling layer has a three-layered structure including an undercoating layer consisting of at least one of a metal and a metal compound, a conductive material layer and an insulating material layer. However, the formation of the conductive material layer made of W can be omitted by increasing the thickness of the Ti layer and the TiN layer. If this is the case, the Ti layer is equivalent to the undercoating layer, and the TiN layer is equivalent to the conductive material layer.

What is claimed is:

1. A semiconductor device characterized by comprising:
a transistor element having a source•drain region, a channel region and a gate electrode formed on a semiconductor substrate;
a first interlayer insulator formed on said transistor element;
a second interlayer insulator formed on said first interlayer insulator;
an interconnecting line formed on said second interlayer insulator;
a conductive material filling layer having at least two layers formed by burying a conductive material in a first hole which is formed in said first interlayer insulator on said source•drain region and exposes not less than 50% of an area of said source•drain region; and
a contact plug formed in a second hole which is formed in said second interlayer insulator and connecting said conductive material filling layer and said interconnecting line.

2. A method of fabricating a semiconductor device, characterized by comprising the steps of:
forming a gate electrode on a semiconductor substrate;
forming a first interlayer insulator on said semiconductor substrate on which said gate electrode is formed;
forming a first hole in said first interlayer insulator;
forming a transistor element having said gate electrode, a source•drain region and a channel region by forming said source•drain region through said first hole in said semiconductor substrate exposed in a bottom portion of said first hole;
forming a conductive material filling layer by burying a conductive material in said first hole;
forming a second interlayer insulator on said first interlayer insulator including said conductive material filling layer and forming a second hole in said second interlayer insulator on said conductive material filling layer; and
forming a contact plug by filling said second hole with a conductive material.

3. A method of fabricating a semiconductor device, characterized by comprising the steps of:
forming a gate electrode, a source•drain region and a channel region on a semiconductor substrate;
forming a first interlayer insulator on said semiconductor substrate on which said gate electrode, said source•drain region and said channel region are formed;
forming a first hole exposing not less than 50% of an area of said source•drain region in said first interlayer insulator;
forming a conductive material filling layer having at least two layers by burying a conductive material in said first hole; and
forming a second hole in a second interlayer insulator on said conductive material filling layer and forming a contact plug by filling said second hole with a conductive material.

4. A semiconductor device characterized by comprising:
a memory cell region in which a memory cell electrically connected to a bit line is arranged;
a non-memory cell region which is formed on a semiconductor substrate on which said memory cell region is formed, and in which a circuit except for said memory cell is arranged; and
a metal layer stacked on a diffusion region formed in said semiconductor substrate in said non-memory cell region, said metal layer being the same layer as said bit line.

5. A device according to claim 4, characterized in that a bit contact for connecting said bit line and said memory cell is made of a material different from said bit line.

6. A device according to claim 4, characterized in that an area of a bottom portion of a bit contact for connecting said bit line and said memory cell is not less than 50% of an area of a diffusion region facing said bit contact.

7. A method of fabricating a semiconductor device, characterized by comprising the steps of:
forming a memory cell on a semiconductor device;
forming a non-memory cell, in which a circuit except for said memory cell is arranged, on said semiconductor substrate;
forming an interlayer insulator on said semiconductor substrate an which said memory cell and said non-memory cell are formed;
forming a contact hole for said memory cell in said interlayer insulator;
forming a bit contact by forming a conductive material in said contact hole;
forming a hole for exposing a diffusion region of said non-memory cell in said interlayer insulator;
forming a metal layer for forming a bit line to be electrically connected to said memory cell via said bit contact and tilling said hole with said metal layer; and
processing said metal layer into patterns corresponding to a pattern of said bit line and a pattern on said diffusion region.

8. A method according to claim 7, characterized in that an area of a bottom portion of said hole is not less than 50% of an area of said diffusion region.
